(19) United States
(12) Patent Application Publication
(10) Pub. No.: US 2026/0121616 A1
(43) Pub. Date: Apr. 30, 2026

(54) Resonator, Filter, Radio Frequency Front-End Module, and Method for Manufacturing a Resonator

(71) Applicant: RADROCK (CHONGQING) MICROELECTRONICS CO., LTD., Chongqing (CN)

(72) Inventors: Bo Du, Chongqing (CN); Tiannian Li, Chongqing (CN); Yang Li, Chongqing (CN); Jianxing Ni, Chongqing (CN)

(21) Appl. No.: 19/488,651

(22) PCT Filed: May 23, 2024
(86) PCT No.: PCT/CN2024/094980

§ 371 Date: Nov. 28, 2025

(30) Foreign Application Priority Data
May 29, 2023 (CN) 202310617422.2
May 29, 2023 (CN) 202310617423.7
May 29, 2023 (CN) 202310617424.1

(51) Int. Cl. H03H 9/56; H03H 9/02

(52) U.S. Cl. CPC H03H 9/568; H03H 9/02015; H03H 9/02574

(57) ABSTRACT

A resonator (1), a filter, a radio frequency (RF) front-end module, and a method for manufacturing the resonator (1) are provided. The resonator (1) includes a piezoelectric substrate (10) and an interdigital transducer (IDT) (30). The first finger (351) includes a first connection portion (3511), a first intermediate portion (3513), and a first main body portion (3515). The second finger (353) includes a second connection portion (3531), a second intermediate portion (3533), and a second main body portion (3535). The potential distribution between an end of the first main body portion (3515) and the first busbar (31), and between an end of the second main body portion (3535) and the second busbar (33), is more uniform, thereby suppressing spurious modes and improving the quality factor (Q factor).

The present application claims priority to Chinese patent applications filed with the China National Intellectual Property Administration (CNIPA) on May 29, 2023, namely: application No. 202310617424.1, entitled “Resonator, Filter, and Radio Frequency Front-End Module”; application No. 202310617423.7, entitled “Resonator, Filter, Radio Frequency Front-End Module, and Method for Manufacturing a Resonator”; and application No. 202310617422.2, entitled “Resonator, Filter, Radio Frequency Front-End Module, and Method for Manufacturing a Resonator.” The entire contents of these applications are incorporated herein by reference.

### TECHNICAL FIELD

The present application relates to the technical field of filters, and in particular, to a resonator, a filter, a radio frequency (RF) front-end module, and a method for manufacturing a resonator.

### BACKGROUND ART

A surface acoustic wave (SAW) resonator is a device that converts electrical signals into acoustic signals or converts acoustic signals into electrical signals. A SAW resonator typically includes a piezoelectric substrate and an interdigital transducer (IDT) formed on the piezoelectric substrate. The IDT can be used to convert electrical signals into acoustic signals or convert acoustic signals into electrical signals.

Spurious modes generated during the operation of a SAW resonator may deteriorate the performance of the resonator. Typically, piston structures can be added at the edges of the IDT active region to suppress lateral spurious modes.

With the development of RF technology, higher performance requirements have been imposed on resonators. Therefore, how to further improve the performance of resonators, especially in terms of spurious mode suppression and quality factor (Q) enhancement, has become an urgent problem to be solved.

### SUMMARY OF THE INVENTION

The present application aims to provide a resonator, a filter, an RF front-end module, and a method for manufacturing a resonator, with the objective of improving at least one of the above-mentioned technical problems. The present application achieves the above purpose through the following technical solutions.

In a first aspect, an embodiment of the present application provides a resonator. The resonator includes a piezoelectric substrate and an interdigital transducer (IDT). The IDT is arranged on the piezoelectric substrate and includes a first busbar and a second busbar arranged opposite to each other on the piezoelectric substrate, and a plurality of finger pairs located between the first busbar and the second busbar. At least one of the plurality of finger pairs includes first fingers and second fingers alternately spaced, the first fingers being connected to the first busbar and spaced apart from the second busbar, and the second fingers being connected to the second busbar and spaced apart from the first busbar. Each of the first fingers includes a first connection portion, a first intermediate portion, and a first main body portion, and each of the second fingers includes a second connection portion, a second intermediate portion, and a second main body portion. The first main body portion and the second main body portion have an overlapping area along a propagation direction of an acoustic wave. The first connection portion is connected to the first busbar, the first intermediate portion is connected between the first connection portion and the first main body portion, and a first gap is provided between the first intermediate portion and an end of the second main body portion. The first connection portion and the first main body portion are offset from each other along the propagation direction of the acoustic wave, and the first intermediate portion and the first main body portion are arranged at an angle. The first busbar, the first connection portion, and the first intermediate portion are connected to form a first opening, and the first opening is oriented away from the first connection portion. The second connection portion is connected to the second busbar, the second intermediate portion is connected between the second connection portion and the second main body portion, and a second gap is provided between the second intermediate portion and the first main body portion. The second connection portion and the second main body portion are offset from each other along the propagation direction of the acoustic wave, and the second intermediate portion and the second connection portion are arranged at an angle. The second busbar, the second connection portion, and the second intermediate portion are connected to form a second opening, and the second opening is oriented in a direction opposite to that of the first opening.

In a second aspect, the embodiments of the present application provide a resonator. The resonator includes a piezoelectric substrate, an interdigital transducer (IDT), and a dielectric layer. The IDT is arranged on the piezoelectric substrate, and the dielectric layer is located on the piezoelectric substrate and covers the IDT. The IDT includes a first busbar and a second busbar arranged opposite to each other on the piezoelectric substrate, a plurality of first fingers, and a plurality of second fingers. The first fingers and the second fingers are alternately arranged. The first fingers are connected to the first busbar and spaced apart from the second busbar, while the second fingers are connected to the second busbar and spaced apart from the first busbar. Each first finger includes a first connection portion, a first intermediate portion, and a first main body portion. Each second finger includes a second connection portion, a second intermediate portion, and a second main body portion. The first main body portion and the second main body portion have an overlapping area in the propagation direction of the acoustic wave. The first connection portion is connected to the first busbar. The first intermediate portion is connected between the first connection portion and the first main body portion, and a first gap is provided between the first intermediate portion and an end of the second main body portion. The first connection portion and the first main body portion are offset from each other along the propagation direction of the acoustic wave, and the first intermediate portion and the first main body portion are arranged at an angle. The first busbar, the first connection portion, and the first intermediate portion are connected to form a first opening, and the first opening is oriented toward the propagation direction of the acoustic wave. The second connection portion is connected to the second busbar. The second intermediate portion is connected between the second connection portion and the second main body portion, and a second gap is provided between the second intermediate portion and the first main body portion. The second connection portion and the second main body portion are offset from each other along the propagation direction of the acoustic wave, and the second intermediate portion and the second connection portion are arranged at an angle. The second busbar, the second connection portion, and the second intermediate portion are connected to form a second opening a second opening, and the second opening is oriented in a direction opposite to that of the first opening.

In a third aspect, the embodiments of the present application provide a resonator. The resonator includes a first dielectric layer and a piezoelectric substrate laminated together, and an interdigital transducer (IDT). The thickness of the first dielectric layer is greater than that of the piezoelectric substrate, and the temperature coefficient of the first dielectric layer is smaller than that of the piezoelectric substrate. The IDT is arranged on a side of the piezoelectric substrate opposite to the first dielectric layer. The IDT includes a first busbar and a second busbar arranged opposite to each other on the piezoelectric substrate, and a plurality of finger pairs located between the first busbar and the second busbar. At least one of the plurality of finger pairs includes first fingers and second fingers alternately arranged. The first fingers are connected to the first busbar and spaced apart from the second busbar, and the second fingers are connected to the second busbar and spaced apart from the first busbar. Each first finger includes a first connection portion, a first intermediate portion, and a first main body portion. Each second finger includes a second connection portion, a second intermediate portion, and a second main body portion. The first main body portion and the second main body portion have an overlapping area along the propagation direction of an acoustic wave. The first connection portion is connected to the first busbar, and the first intermediate portion is connected between the first connection portion and the first main body portion. The first connection portion and the first main body portion are offset from each other along the propagation direction of the acoustic wave, and the first intermediate portion and the first main body portion are arranged at an angle. The second connection portion is connected to the second busbar, and the second intermediate portion is connected between the second connection portion and the second main body portion. The second connection portion and the second main body portion are offset from each other along the propagation direction of the acoustic wave, and the second intermediate portion and the second connection portion are arranged at an angle. The first intermediate portion is located between the first connection portion and the second main body portion, with a first gap provided between the first intermediate portion and an end of the second main body portion. The second intermediate portion is located between the second connection portion and the first main body portion, with a second gap provided between the second intermediate portion and the first main body portion.

In a fourth aspect, the embodiments of the present application provide a resonator. The resonator includes a piezoelectric substrate, an interdigital transducer (IDT), and a temperature compensation layer, with the piezoelectric substrate being made of lithium niobate. The IDT is arranged on the piezoelectric substrate, and the temperature compensation layer covers a surface of the IDT opposite to the piezoelectric substrate. The temperature compensation layer is configured to adjust a frequency temperature coefficient of the resonator. The IDT includes two electrode assemblies arranged opposite to each other. Each electrode assembly includes a busbar and a plurality of fingers connected thereto. At least one of the fingers is a bent finger. The bent finger includes, in sequence, a connection portion, an intermediate portion, and a main body portion. One end of the connection portion is connected to the busbar, the other end of the connection portion is connected to one end of the intermediate portion, and the other end of the intermediate portion is connected to the main body portion. The connection portion and the intermediate portion are arranged at an angle, and the main body portion and the intermediate portion are arranged at an angle. The intermediate portion, the connection portion, and the busbar form an opening oriented away from the connection portion. The connection portion and the main body portion are offset from each other along the propagation direction of an acoustic wave. The fingers of the two electrode assemblies are alternately spaced and have an overlapping area along the propagation direction of the acoustic wave. A gap is provided between the intermediate portion of the bent finger of one electrode assembly and the main body portion of the bent finger of the other electrode assembly.

In a fifth aspect, the embodiments of the present application provide a filter, which includes any one of the resonators according to the above embodiments.

In a sixth aspect, the embodiments of the present application provide a radio frequency (RF) front-end module, which includes the filter according to the above embodiments.

In a seventh aspect, the embodiments of the present application provide a method for manufacturing a resonator, the method including: providing a piezoelectric substrate; and forming an interdigital transducer (IDT) on the piezoelectric substrate, the IDT including a first busbar and a second busbar arranged opposite to each other on the piezoelectric substrate, and a plurality of finger pairs located between the first busbar and the second busbar. At least one of the plurality of finger pairs includes first fingers and second fingers alternately spaced, the first fingers being connected to the first busbar and spaced apart from the second busbar, and the second fingers being connected to the second busbar and spaced apart from the first busbar. Each of the first fingers includes a first connection portion, a first intermediate portion, and a first main body portion, and each of the second fingers includes a second connection portion, a second intermediate portion, and a second main body portion; the first main body portion and the second main body portion have an overlapping area along a propagation direction of an acoustic wave. The first connection portion is connected to the first busbar, the first intermediate portion is connected between the first connection portion and the first main body portion, and a first gap is provided between the first intermediate portion and an end of the second main body portion; the first connection portion and the first main body portion are offset from each other along the propagation direction of the acoustic wave, and the first intermediate portion and the first main body portion are arranged at an angle; the first busbar, the first connection portion, and the first intermediate portion are connected to form a first opening, and the first opening is oriented away from the first connection portion. The second connection portion is connected to the second busbar, the second intermediate portion is connected between the second connection portion and the second main body portion, and a second gap is provided between the second intermediate portion and the first main body portion; the second connection portion and the second main body portion are offset from each other along the propagation direction of the acoustic wave, and the second intermediate portion and the second connection portion are arranged at an angle; the second busbar, the second connection portion, and the second intermediate portion are connected to form a second opening, and the second opening is oriented in a direction opposite to that of the first opening.

In an eighth aspect, the embodiments of the present application provide a method for manufacturing a resonator, the method including: providing a piezoelectric substrate, with the piezoelectric substrate being made of lithium niobate; forming an interdigital transducer (IDT) on the piezoelectric substrate. The IDT includes two electrode assemblies arranged opposite to each other, with each electrode assembly including a busbar and a plurality of fingers connected thereto, at least one of the fingers being a bent finger. The bent finger includes, in sequence, a connection portion, an intermediate portion, and a main body portion; one end of the connection portion is connected to the busbar, another end of the connection portion is connected to one end of the intermediate portion, and another end of the intermediate portion is connected to the main body portion; the connection portion and the intermediate portion are arranged at an angle, the main body portion and the intermediate portion are arranged at an angle; the intermediate portion, the connection portion, and the busbar form an opening oriented away from the connection portion, and the connection portion and the main body portion are offset from each other along a propagation direction of an acoustic wave. The fingers of the two electrode assemblies are alternately spaced, have an overlapping area along the propagation direction of the acoustic wave, and a gap is provided between the intermediate portion of the bent finger of one electrode assembly and the main body portion of the bent finger of the other electrode assembly; forming a temperature compensation layer on a surface of the IDT opposite to the piezoelectric substrate, the temperature compensation layer being configured to adjust a frequency temperature coefficient of the resonator; and forming a frequency tuning layer over the temperature compensation layer.

The resonator, filter, RF front-end module, and method for manufacturing a resonator provided in the embodiments of the present application include a resonator including a piezoelectric substrate and an interdigital transducer (IDT), with the IDT arranged on the piezoelectric substrate. Each first finger includes a first connection portion, a first intermediate portion, and a first main body portion, and each second finger includes a second connection portion, a second intermediate portion, and a second main body portion. The first main body portion and the second main body portion have an overlapping area along a propagation direction of an acoustic wave. The first connection portion is connected to the first busbar, and the first intermediate portion is connected between the first connection portion and the first main body portion, with a first gap provided between the first intermediate portion and an end of the second main body portion. The first connection portion and the first main body portion are offset from each other along the propagation direction of the acoustic wave, and the first intermediate portion and the first main body portion are arranged at an angle. The first busbar, the first connection portion, and the first intermediate portion are connected to form a first opening oriented away from the first connection portion. The second connection portion is connected to the second busbar, and the second intermediate portion is connected between the second connection portion and the second main body portion, with a second gap provided between the second intermediate portion and the first main body portion. The second connection portion and the second main body portion are offset from each other along the propagation direction of the acoustic wave, and the second intermediate portion and the second connection portion are arranged at an angle. The second busbar, the second connection portion, and the second intermediate portion are connected to form a second opening oriented in a direction opposite to that of the first opening. In the SAW resonator, by altering the shape of the finger in the gap region between the end of the main body portion and the busbar, the potential difference in the gap region can be reduced, thereby weakening the intensity of the excitation source located in the gap region and suppressing secondary excitation of the excitation source, which effectively inhibits spurious modes. Moreover, the resonator provided in the embodiments of the present application can suppress spurious modes, including lateral spurious modes, by modifying the shape of the fingers, without requiring a piston structure in the overlapping area. This avoids the piston structure from limiting the width of the fingers or the spacing between two adjacent fingers, thereby preventing restrictions on the operating frequency band of the resonator. Under the same process conditions, this allows for an increase in the resonator frequency or a reduction in the resonator size at the same frequency.

### BRIEF DESCRIPTION OF THE DRAWINGS

To more clearly illustrate the technical solutions of the embodiments of the present application, the drawings used in the embodiments are briefly described below. It should be understood that the drawings below only depict certain embodiments of the present application. Those skilled in the art may derive additional drawings from these without exercising inventive effort.

FIG. 1 is a top-view schematic of a resonator provided by an embodiment of the present application.

FIG. 2 is a cross-sectional schematic of the resonator shown in FIG. 1.

FIG. 3 is a schematic of the IDT structure in FIG. 1.

FIG. 4 is a graph of frequency versus admittance of the acoustic wave of the resonator shown in FIG. 1.

FIG. 5 is a graph of frequency versus quality factor of the acoustic wave of the resonator shown in FIG. 1.

FIG. 6 is another schematic of the IDT structure in FIG. 1.

FIG. 7 is another schematic of the IDT structure in FIG. 1.

FIG. 8 is another schematic of the IDT structure in FIG. 1.

FIG. 9 is another schematic of the IDT structure in FIG. 1.

FIG. 10 is another schematic of the IDT structure in FIG. 1.

FIG. 11 is another schematic of the IDT structure in FIG. 1.

FIG. 12 is another schematic of the IDT structure in FIG. 1.

FIG. 13 is another schematic of the IDT structure in FIG. 1.

FIG. 14 is another schematic of the IDT structure in FIG. 1.

FIG. 15 is a flowchart illustrating a method for manufacturing the resonator provided by an embodiment of the present application.

FIG. 16 is a cross-sectional schematic of a piezoelectric film SAW resonator provided by an embodiment of the present application.

FIG. 17 is a grayscale map showing the potential distribution of a related-art resonator.

FIG. 18 is a grayscale map showing the potential distribution of the resonator of the present application.

FIG. 19 is a graph of frequency versus admittance of a related-art resonator.

FIG. 20 is a graph of frequency versus admittance of the resonator shown in FIG. 16.

FIG. 21 is a comparison graph of frequency versus admittance between a related-art resonator and the resonator of the present application.

FIG. 22 is a comparison graph of frequency versus the real part of admittance between a related-art resonator and the resonator of the present application.

FIG. 23 is a comparison graph of Q factors between a related-art resonator and the resonator of the present application.

FIG. 24 is a graph of frequency versus admittance of a related-art resonator having a piston structure.

FIG. 25 is a graph of frequency versus admittance of another related-art resonator having a piston structure.

FIG. 26 is a graph of frequency versus admittance of the resonator shown in FIG. 10.

FIG. 27 is a comparison graph of Q factors between a related-art resonator and the resonator provided by an embodiment of the present application.

FIG. 28 is a schematic of an IDT having dummy fingers and a piston structure provided by another embodiment of the present application.

FIG. 29 is a cross-sectional schematic of a TC-SAW resonator provided by an embodiment of the present application.

FIG. 30 is another graph of frequency versus admittance of the resonator shown in FIG. 1.

FIG. 31 is another graph of frequency versus admittance of the resonator shown in FIG. 1.

FIG. 32 is another schematic of the IDT structure in FIG. 1.

FIG. 33 is a flowchart illustrating a method for manufacturing the TC-SAW resonator provided by an embodiment of the present application.

### DETAILED DESCRIPTION OF THE EMBODIMENTS

The embodiments of the present application are described in detail below, with examples illustrated in the accompanying drawings. Like reference numerals throughout the drawings indicate like or similar components, or components having like or similar functions. The embodiments described below are exemplary and intended only to explain the present application, and should not be construed as limiting the scope of the present application.

To enable those skilled in the art to better understand the solutions of the present application, the technical schemes are described clearly and comprehensively in conjunction with the accompanying drawings. It is apparent that the described embodiments represent only a portion of the embodiments of the present application, not all possible embodiments. Any other embodiments derived from these embodiments by those skilled in the art without inventive effort are also intended to fall within the scope of protection of the present application.

The resonator provided in the present application can be applied to conventional surface acoustic wave (SAW) resonators, TC-SAW (Temperature Compensated SAW) resonators, piezoelectric thin-film SAW resonators, X-BAR (laterally excited film bulk acoustic wave) resonators, and other resonators including an IDT; the present application is not limited thereto.

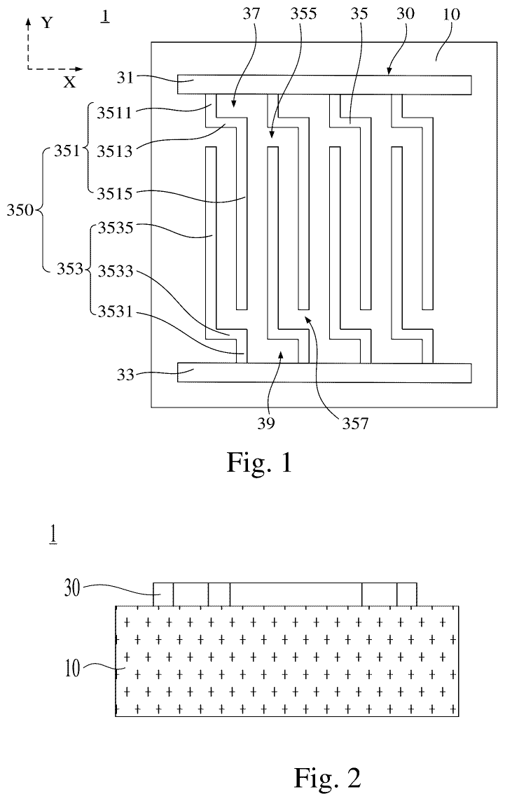

Referring to FIGS. 1 to 3, an embodiment of the present application provides a resonator 1, which includes a piezoelectric substrate 10 and an IDT 30. The IDT 30 is arranged on the piezoelectric substrate 10 and includes a first busbar 31 and a second busbar 33 arranged opposite to each other on the piezoelectric substrate 10, as well as a plurality of finger pairs located between the first busbar 31 and the second busbar 33. At least one of the plurality of finger pairs 350 includes first fingers 351 and second fingers 353 alternately spaced. The first fingers 351 are connected to the first busbar 31 and spaced apart from the second busbar 33, and the second fingers 353 are connected to the second busbar 33 and spaced apart from the first busbar 31.

Each first finger 351 includes a first connection portion 3511, a first intermediate portion 3513, and a first main body portion 3515, and each second finger 353 includes a second connection portion 3531, a second intermediate portion 3533, and a second main body portion 3535. The first main body portion 3515 and the second main body portion 3535 have an overlapping area along the propagation direction of an acoustic wave. The first connection portion 3511 is connected to the first busbar 31, and the first intermediate portion 3513 is connected between the first connection portion 3511 and the first main body portion 3515, with a first gap 355 provided between the first intermediate portion 3513 and an end of the second main body portion 3535. The first connection portion 3511 and the first main body portion 3515 are offset from each other along the propagation direction of the acoustic wave, and the first intermediate portion 3513 and the first main body portion 3515 are arranged at an angle. The first busbar 31, the first connection portion 3511, and the first intermediate portion 3513 are connected to form a first opening 37 oriented away from the first connection portion 3511. The second connection portion 3531 is connected to the second busbar 33, and the second intermediate portion 3533 is connected between the second connection portion 3531 and the second main body portion 3535, with a second gap 357 provided between the second intermediate portion 3533 and the first main body portion 3515. The second connection portion 3531 and the second main body portion 3535 are offset from each other along the propagation direction of the acoustic wave, and the second intermediate portion 3533 and the second connection portion 3531 are arranged at an angle. The second busbar 33, the second connection portion 3531, and the second intermediate portion 3533 are connected to form a second opening 39, with the second opening 39 oriented in the direction opposite to that of the first opening 37.

Accordingly, the shape of the first finger 351 in the gap region between the end of the second main body portion 3535 and the first busbar 31, as well as the shape of the second finger 353 in the gap region between the end of the first main body portion 3515 and the second busbar 33, is altered. This reduces the potential difference in the gap regions and weakens the intensity of the excitation sources located therein, thereby suppressing secondary excitation of the sources and effectively inhibiting spurious modes.

Specifically, in the IDT 30, one end of the first connection portion 3511 is connected to the first busbar 31, and the other end is connected to the first intermediate portion 3513. The other end of the first intermediate portion 3513 is connected to the first main body portion 3515, with a first gap 355 provided between the first intermediate portion 3513 and the second main body portion 3535. The first connection portion 3511, the first intermediate portion 3513, and the first busbar 31 form a first opening 37. One end of the second connection portion 3531 is connected to the second busbar 33, and the other end is connected to the second intermediate portion 3533. The other end of the second intermediate portion 3533 is connected to the second main body portion 3535, with a second gap 357 provided between the second intermediate portion 3533 and the first main body portion 3515. The second connection portion 3531, the second intermediate portion 3533, and the second busbar 33 form a second opening 39 oriented opposite to the first opening 37. As a result, the potential difference in the gap regions is reduced, and the intensity of the excitation sources located in the gap regions is weakened, helping suppress secondary excitation of the sources and reducing stray acoustic waves. Spurious modes are thus effectively suppressed, including those originating in the gap regions and lateral spurious modes. Compared to finger structures without openings, this configuration provides improved suppression of spurious modes.

As shown in FIG. 1, the propagation direction of the acoustic wave is defined as the X direction, i.e., the propagation direction of the primary mode of the acoustic wave is along the X direction. The extension direction of the first main body portion 3515 or the second main body portion 3535 (from the first busbar 31 toward the second busbar 33) is defined as the Y direction, which is perpendicular to the X direction.

It can be understood that the intermediate portions (the first intermediate portion 3513 and the second intermediate portion 3533) are arranged at an angle with respect to the connection portions (the first connection portion 3511 and the second connection portion 3531) and the main body portions (the first main body portion 3515 and the second main body portion 3535). The angle may be acute, obtuse, or right, such that the fingers (the first finger 351 and the second finger 353) can have a bent shape within the gap regions.

Furthermore, since the first connection portion 3511 and the first main body portion 3515 are offset from each other along the propagation direction of the acoustic wave, the first intermediate portion 3513 and the first main body portion 3515 are arranged at an angle, and the first busbar 31, the first connection portion 3511, and the first intermediate portion 3513 are connected to form a first opening 37 oriented away from the first connection portion 3511, the resonator can better suppress spurious modes compared to a resonator without the above offset, angled arrangement, and opening.

In this embodiment, the IDT 30 includes a plurality of fingers 35, which can be arranged with spacing between them and are alternately connected to the first busbar 31 and the second busbar 33. In each pair of adjacent fingers 35, one is connected to the first busbar 31 and the other is connected to the second busbar 33, and they can be regarded as a finger pair. Specifically, for ease of understanding, taking four fingers 35 as an example, they are named the first finger, the second finger, the third finger, and the fourth finger. The first, second, third, and fourth fingers are sequentially spaced apart. The first finger is connected to the first busbar 31 and spaced from the second busbar 33; the second finger is connected to the second busbar 33 and spaced from the first busbar 31. The first and second fingers can be regarded as one finger pair. The third finger is connected to the first busbar 31 and spaced from the second busbar 33; the fourth finger is connected to the second busbar 33 and spaced from the first busbar 31. The third and fourth fingers can be regarded as another finger pair. The first, second, third, and fourth fingers have overlapping central areas along the X direction, where the acoustic wave primarily propagates. A first gap region is formed between the first busbar 31 and the central area, and a second gap region is formed between the second busbar 33 and the central area. The acoustic wave velocity in the central area is lower than that in the first and second gap regions, thereby preventing the acoustic wave from leaking into the lateral gap regions (the first and second gap regions).

It can be understood that among the plurality of finger pairs, at least one finger pair 350 exists. The number of finger pairs 350 may be one, two, three, four, and so on, or each finger pair included in IDT 30 may adopt the structure of the finger pair 350.

As an example, the first and second fingers can form one finger pair 350, where the first finger serves as the first finger 351 and the second finger serves as the second finger 353. In this case, the third and fourth fingers can be ordinary fingers; for instance, the third finger may extend linearly from the first busbar 31 toward the second busbar 33, and the fourth finger may extend linearly from the second busbar 33 toward the first busbar 31.

As another example, the first and second fingers can form one finger pair 350, and the third and fourth fingers can form another finger pair 350. In this case, the first and third fingers can each serve as an individual first finger 351, and the second and fourth fingers can each serve as an individual second finger 353.

It can be understood that when only some of the fingers 35 included in the IDT 30 adopt the finger pair 350 structure, the remaining fingers 35 outside the finger pair 350 can be ordinary fingers. That is, the shape of the ordinary fingers in the first gap region and the second gap region remains unchanged. The ordinary fingers can extend linearly from the first busbar 31 toward the second busbar 33 while spaced from the second busbar 33, or extend linearly from the second busbar 33 toward the first busbar 31 while spaced from the first busbar 31.

Moreover, in conventional resonators, lateral spurious modes are typically suppressed by providing piston structures (i.e., widening and/or thickening the fingers). Due to process limitations, the presence of these piston structures restricts the width of the fingers or the spacing between adjacent fingers, thereby limiting the operating frequency range of the resonator. In contrast, the resonator 1 provided in the present embodiment can suppress spurious modes, including lateral spurious modes, simply by modifying the shape of the fingers 35. This eliminates the need to provide piston structures in the overlapping region, thereby avoiding the restrictions on finger width or spacing imposed by piston structures and preventing limitations on the operating frequency range of the resonator 1. Under the same process conditions, this can either increase the operating frequency of the resonator 1 or reduce its size at the same frequency. Furthermore, because the resonator 1 in the present embodiment does not require piston structures in the overlapping region, the manufacturing process of the resonator 1 can be simplified. This design not only suppresses lateral spurious modes but also suppresses spurious modes generated in the gap regions.

Referring to FIG. 4, the horizontal axis represents the frequency of the acoustic wave, and the vertical axis represents the admittance. The solid line represents the resonator 1 in the present embodiment, which does not employ piston structures but instead modifies the shape of the fingers 35 within the gap regions. The dashed line represents a conventional resonator using piston structures without modifying the shape of the fingers 35 within the gap regions. As shown in the figure, compared with the conventional resonator, the resonator 1 of the present embodiment exhibits a smoother admittance curve, and sharp spurious peaks are significantly flattened. Therefore, the resonator 1 in the present embodiment can effectively suppress spurious modes without the need for piston structures.

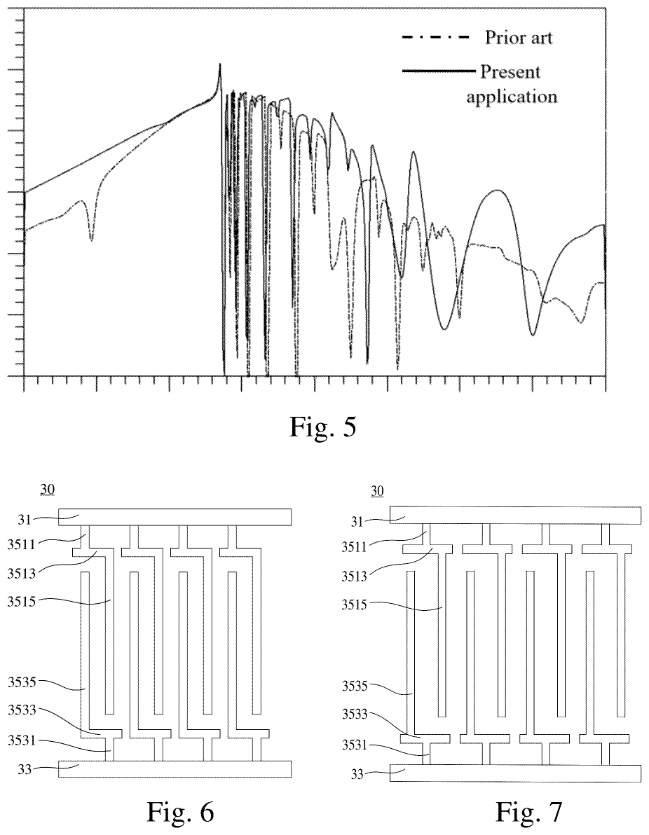

Referring to FIG. 5, the horizontal axis represents the frequency of the acoustic wave, and the vertical axis represents the quality factor (Q factor). The solid line represents the resonator 1 in the present embodiment, which does not employ piston structures but modifies the shape of the fingers 35 within the gap regions. The dashed line represents a conventional resonator using piston structures without modifying the shape of the fingers 35 in the gap regions. As shown in the figure, the Q factor of the resonator 1 in the present embodiment is significantly higher than that of the conventional resonator. Therefore, the structure of the resonator 1 in the present embodiment can effectively improve the Q factor without requiring piston structures.

In some embodiments, the piezoelectric substrate 10 can be made of a piezoelectric material. For example, the piezoelectric substrate 10 can be made of quartz, aluminum nitride (AlN), sapphire, lithium niobate (LiNbO₃, LN), lithium tantalate (LiTaO₃, LT), or other similar materials.

In some embodiments, the resonator 1 can be applied to piezoelectric thin-film SAW resonators.

Currently, in the prior art, a piezoelectric thin-film SAW resonator typically includes a substrate, a piezoelectric substrate, and an IDT on the piezoelectric substrate. The substrate and the IDT are arranged on opposite sides of the piezoelectric substrate. By placing the substrate beneath the piezoelectric substrate, energy leakage in the depth direction can be limited, which improves the Q factor of the resonator. However, this configuration significantly increases both the intensity and complexity of spurious modes in the piezoelectric thin-film SAW resonator, thereby deteriorating its operational performance. To reduce the strength of lateral modes, the prior art typically adds piston structures on opposite sides of the IDT working region, increasing the mass loading of the IDT on both sides of the working region. For piezoelectric thin-film SAW resonators, however, this approach cannot suppress spurious modes generated in the gap regions, and the suppression effect on lateral spurious modes is also not ideal.

Referring to FIGS. 1, 3, and 16, when resonator 1 is a piezoelectric thin-film SAW resonator, resonator 1 includes a piezoelectric substrate 10 and a first dielectric layer 40 arranged in a stacked manner, as well as an IDT 30.

The thickness of the first dielectric layer 40 is greater than that of the piezoelectric substrate 10, and the temperature coefficient of the first dielectric layer 40 is smaller than that of the piezoelectric substrate 10. Accordingly, the first dielectric layer 40 can provide temperature compensation for the piezoelectric substrate 10 to reduce the frequency temperature coefficient of resonator 1, thereby improving the effect of temperature on acoustic wave propagation and enhancing the operating performance of resonator 1. Moreover, by providing a thicker first dielectric layer 40 with higher acoustic velocity and lower temperature coefficient below the piezoelectric substrate 10, the acoustic velocity of the piezoelectric substrate 10 can also be increased.

The first dielectric layer 40 can serve as a substrate for resonator 1 and can be made of materials such as silicon, quartz, sapphire, or silicon carbide.

IDT 30 is disposed on the side of piezoelectric substrate 10 opposite to the first dielectric layer 40 and includes a first busbar 31 and a second busbar 33 arranged opposite to each other on the piezoelectric substrate 10, as well as a plurality of finger pairs located between the first busbar 31 and the second busbar 33. At least one of the finger pairs 350 includes alternately arranged first fingers 351 and second fingers 353, with the first fingers 351 connected to the first busbar 31 and spaced apart from the second busbar 33, and the second fingers 353 connected to the second busbar 33 and spaced apart from the first busbar 31. Each first finger 351 includes a first connection portion 3511, a first intermediate portion 3513, and a first main body portion 3515. Each second finger 353 includes a second connection portion 3531, a second intermediate portion 3533, and a second main body portion 3535. The first main body portion 3515 and the second main body portion 3535 have an overlapping area along the propagation direction of the acoustic wave. One end of the first connection portion 3511 is connected to the first busbar 31, and the other end is connected to the first intermediate portion 3513. The first intermediate portion 3513 is disposed between the first connection portion 3511 and the first main body portion 3515. The first connection portion 3511 and the first main body portion 3515 are offset from each other along the propagation direction of the acoustic wave, and the first intermediate portion 3513 and the first main body portion 3515 are arranged at an angle. One end of the second connection portion 3531 is connected to the second busbar 33, and the other end is connected to the second intermediate portion 3533. The second intermediate portion 3533 is disposed between the second connection portion 3531 and the second main body portion 3535. The second connection portion 3531 and the second main body portion 3535 are offset from each other along the propagation direction of the acoustic wave, and the second intermediate portion 3533 and the second connection portion 3531 are arranged at an angle. The first intermediate portion 3513 is located between the first connection portion 3511 and the second main body portion 3535 and has a first gap 355 with the end of the second main body portion 3535. The second intermediate portion 3533 is located between the second connection portion 3531 and the first main body portion 3515 and has a second gap 357 with the first main body portion 3515.

Accordingly, the shapes of the first finger 351 and the second finger 353 in the gap regions between the end of the second main body portion 3535 and the first busbar 31, and between the end of the first main body portion 3515 and the second busbar 33, have been modified. This can reduce the potential difference in the gap regions and weaken the intensity of the excitation source located in the gap regions, thereby suppressing secondary excitation of the excitation source, reducing stray acoustic waves, and effectively suppressing spurious modes. That is, the spurious modes generated in the gap regions are suppressed, and lateral spurious modes are also more effectively suppressed.

Referring to FIG. 17, FIG. 17 illustrates a piezoelectric thin-film SAW resonator in the related art that employs piston structures. In the upper portion of FIG. 17, the graph shows the acoustic wave frequency on the horizontal axis and the admittance on the vertical axis. From the graph, it can be seen that the lower curve has multiple pronounced peaks, which represent spurious modes (stray acoustic waves). Taking the peaks within the circular dashed region of the graph as an example, the corresponding acoustic wave frequency is approximately 1.95 GHz. The lower portion of FIG. 17 shows the potential distribution when the acoustic wave frequency is 1.95 GHz. The upper part of the potential distribution shows a color map, and the lower part shows a grayscale map of the potential distribution. As can be seen from FIG. 17, when the acoustic wave is at 1.95 GHz, the potential distribution ranges approximately from −2 V to 2 V, giving a potential difference of about 4 V. The maximum and minimum values are located in the first and second gap regions, respectively (the maximum is roughly in the dashed box on the left side of the potential map, and the minimum is roughly in the dashed box on the right side). At this time, the large potential difference causes the excitation source in the gap regions to undergo secondary excitation, resulting in the generation of spurious modes.

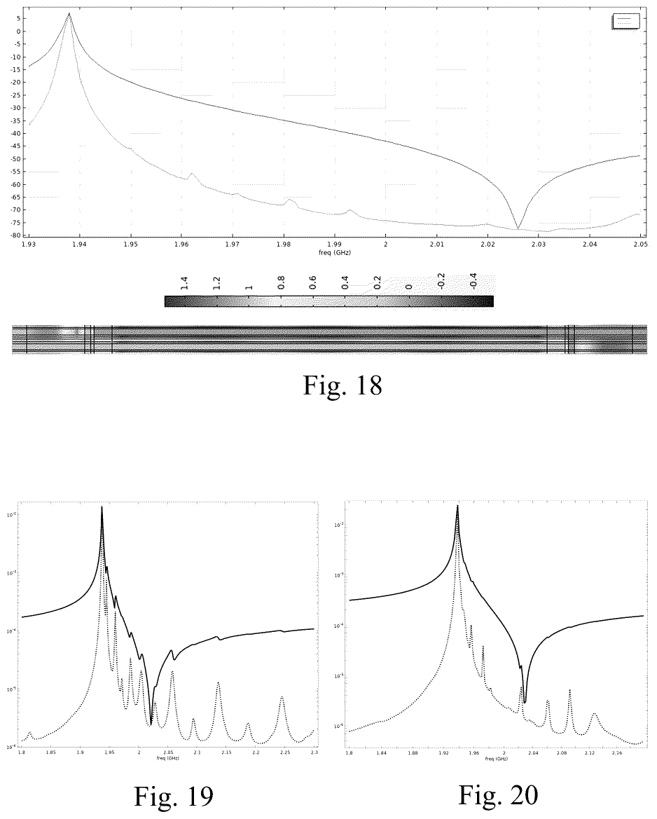

Referring to FIG. 18, FIG. 18 illustrates the thin-film SAW resonator 1 of the present embodiment, in which no piston structures are employed, and the finger shapes are modified within the gap regions. In the upper portion of FIG. 18, the graph shows the acoustic wave frequency on the horizontal axis and the admittance on the vertical axis. From the graph, it can be seen that the peaks in the lower curve of FIG. 18 are significantly flatter than the peaks in the lower curve of FIG. 17. That is, the resonator 1 provided by the present embodiment significantly reduces the intensity of spurious modes. The lower portion of FIG. 18 shows the potential distribution when the acoustic wave frequency is 1.95 GHz. The upper part of the potential distribution shows a color map, and the lower part shows a grayscale map of the potential distribution. As can be seen from FIG. 18, when the acoustic wave is at 1.95 GHz (circular dashed region), the potential distribution ranges approximately from −0.2 V to 1.2 V, giving a potential difference of about 1.4 V. The maximum and minimum values are located in the first gap region and the second gap region, respectively (i.e., on the left and right sides of the potential map). At this time, the potential difference is significantly smaller than that in FIG. 17, and the potential distribution is more uniform compared to FIG. 17. Therefore, compared with the resonator in the related art that employs piston structures, the resonator 1 of the present embodiment reduces the potential difference in the gap regions by modifying the shape of the first finger 351 in the first gap region and the shape of the second finger 353 in the second gap region. This weakens the intensity of the excitation sources in the gap regions, suppresses secondary excitation of the excitation sources, reduces stray acoustic waves, and effectively suppresses spurious modes. That is, spurious modes generated in the gap regions are suppressed, and lateral spurious modes are also more effectively suppressed.

Referring also to FIGS. 19 and 20, the horizontal axes of both figures represent the acoustic wave frequency, and the vertical axes represent the admittance. FIG. 19 shows the acoustic wave frequency versus admittance curve of a resonator in the related art, i.e., a resonator composed of ordinary fingers whose shapes in the gap regions are not modified. FIG. 20 shows the acoustic wave frequency versus admittance curve of the resonator 1 provided by the present embodiment, i.e., a resonator 1 including at least one finger pair 350 whose shapes are modified within the gap regions. From the figures, it can be seen that the curve in FIG. 19 exhibits multiple peaks and valleys, whereas the curve in FIG. 20 is noticeably smoother. Therefore, by modifying the shape of the first finger 351 in the first gap region and the shape of the second finger 353 in the second gap region, the present embodiment enables smoother propagation of the acoustic waves, reducing stray acoustic waves and thereby suppressing spurious modes.

In summary, the resonator 1 provided by the present embodiment reduces the potential differences between the end of the second main body portion 3535 and the first busbar 31, and between the end of the first main body portion 3515 and the second busbar 33, by modifying the shape of the first finger 351 in the gap region between the second main body portion 3535 and the first busbar 31 and the shape of the second finger 353 in the gap region between the first main body portion 3515 and the second busbar 33. This suppresses secondary excitation of the excitation sources in the gap regions, reduces stray acoustic waves, and helps effectively suppress spurious modes of the acoustic waves.

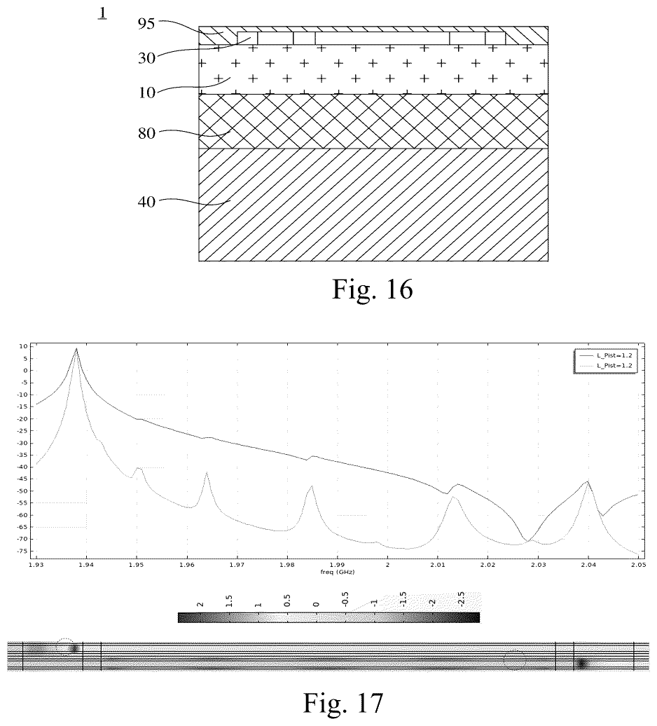

In some embodiments, when the resonator 1 is a piezoelectric thin-film SAW resonator, as shown in FIG. 16, the resonator 1 further includes a second dielectric layer 80 located between the first dielectric layer 40 and the piezoelectric substrate 10. The thicknesses of the second dielectric layer 80 and the piezoelectric substrate 10 are both smaller than the thickness of the first dielectric layer 40, and the acoustic velocities of the piezoelectric substrate 10 and the first dielectric layer 40 are both greater than the acoustic velocity of the second dielectric layer 80, which helps reduce longitudinal leakage of the acoustic wave energy.

It can be understood that the second dielectric layer 80 may be a single-layer film, in which case the second dielectric layer 80 is a first film layer. The first film layer can be a low acoustic velocity layer or a low acoustic impedance layer, while the first dielectric layer 40 can be a high acoustic velocity layer or a high acoustic impedance layer. The arrangement of the first dielectric layer 40 and the second dielectric layer 80 not only provides temperature compensation for the piezoelectric substrate 10, but also forms an acoustic reflection structure below the piezoelectric substrate 10, reducing longitudinal leakage of acoustic wave energy.

Optionally, the second dielectric layer 80 may also be a multi-layer film. In the multi-layer film, at least one layer is the first film layer, and specifically, there may be multiple first film layers. Optionally, the multi-layer film may be a stacked structure in which layers of high and low acoustic impedance or high and low acoustic velocity are alternately arranged, which can further suppress longitudinal leakage of acoustic wave energy. Here, “longitudinal” generally refers to the thickness direction of the piezoelectric substrate 10.

Specifically, the first film layer may be made of silicon dioxide, fluorine-doped silicon oxide, or the like.

In some embodiments, the thicknesses of the piezoelectric substrate 10 and the second dielectric layer 80 can each be less than 5 μm, so that the piezoelectric substrate 10 can achieve better temperature compensation. The thicknesses of the piezoelectric substrate 10 and the second dielectric layer 80 may be the same or different.

It should be noted that when the second dielectric layer 80 is a multilayer film, the thickness of each individual layer can be less than 5 μm, or the total thickness of the second dielectric layer 80 can be less than 5 μm. No limitation is made in this regard.

As an example, the thicknesses of the piezoelectric substrate 10 and the second dielectric layer 80 can be 4 μm, 3 μm, etc. The present application is not limited in this respect.

In some embodiments, the thickness of the first dielectric layer 40 can be greater than or equal to 50 μm, so that the first dielectric layer 40 can achieve more stable physical properties and can more reliably provide temperature compensation for the piezoelectric substrate 10. For example, the thickness of the first dielectric layer 40 can be 50 μm, 100 μm, 200 μm, 300 μm, etc. The present application is not limited in this respect.

In some embodiments, when the resonator 1 is a piezoelectric thin-film SAW resonator, the piezoelectric substrate 10 can be made of piezoelectric materials such as lithium tantalate or lithium niobate. The cut type can be 42° Y-X, 50° Y-X, or other cuts of lithium tantalate, or 41° Y-X, 5° Y-X, 163° Y-X, or other cuts of lithium niobate. The present application is not limited in this respect.

Referring to FIGS. 1, 3, and 29, in some embodiments, the resonator 1 can also be a temperature-compensated resonator, such as a TC-SAW resonator. When the resonator 1 is a TC-SAW resonator, the resonator 1 includes the piezoelectric substrate 10, the IDT 30, and a temperature compensation layer 70.

In some embodiments, the piezoelectric substrate 10 can be made of lithium niobate. Compared with other piezoelectric materials, lithium niobate provides more flexibility in selecting the cut type, which can improve the electromechanical coupling coefficient of the resonator 1 and increase the filter bandwidth.

The IDT 30 is disposed on the piezoelectric substrate 10, and the temperature compensation layer 70 covers the surface of the IDT 30 opposite to the piezoelectric substrate 10. The temperature compensation layer 70 is configured to adjust the frequency temperature coefficient of the resonator 1, thereby improving the stability of the acoustic wave frequency with respect to temperature and helping to reduce the impact of temperature variation on the working frequency band of the resonator 1.

IDT 30 includes two oppositely arranged electrode assemblies, each electrode assembly including a busbar and a plurality of fingers connected to the busbar, wherein at least one of the fingers is a bent finger. The bent finger includes a connection portion, an intermediate portion, and a main body portion connected in sequence, one end of the connection portion being connected to the busbar, the other end of the connection portion being connected to one end of the intermediate portion, and the other end of the intermediate portion being connected to the main body portion. The connection portion and the intermediate portion are arranged at an angle, and the main body portion and the intermediate portion are arranged at an angle, such that an opening is formed between the intermediate portion, the connection portion, and the busbar, facing away from the connection portion. The connection portion and the main body portion have a distance difference along the propagation direction of the acoustic wave. The fingers of the two electrode assemblies are alternately spaced and have an overlapping region along the propagation direction of the acoustic wave. A gap exists between the intermediate portion of the bent finger in one electrode assembly and the main body portion of the bent finger in the other electrode assembly. As a result, the shape of the bent finger in the gap region between the end of the main body portion and the busbar is changed, which can reduce the intensity of the excitation source in the gap region, thereby suppressing secondary excitation of the excitation source, reducing spurious acoustic waves, and effectively suppressing not only transverse spurious modes but also spurious modes generated in the gap region.

Referring to FIGS. 1, 3, and 32, it should be noted that the bent fingers are generally arranged in pairs. For ease of understanding, the two electrode assemblies are hereinafter referred to as a first electrode assembly and a second electrode assembly. The busbar and fingers included in the first electrode assembly correspond to the first busbar 31 and the first fingers 351 in the above embodiments. The bent finger included in the first electrode assembly's fingers 35 is referred to as a first bent finger 50, wherein the connection portion, intermediate portion, and main body portion of the first bent finger 50 correspond to the first connection portion 3511, the first intermediate portion 3513, and the first main body portion 3515 in the above embodiments. It is to be understood that the first electrode assembly includes the first busbar 31 and a plurality of first fingers 351 connected thereto, and at least one of the first fingers 351 is a first bent finger 50.

The busbar and fingers included in the second electrode assembly correspond to the second busbar 33 and the second fingers 353 in the above embodiments. The bent finger included in the second electrode assembly's fingers is referred to as a second bent finger 60. It is to be understood that the second electrode assembly includes the second busbar 33 and a plurality of second fingers 353 connected thereto. The first busbar 31 and the second busbar 33 are arranged opposite to each other, and the plurality of first fingers 351 and the plurality of second fingers 353 are both located between the first busbar 31 and the second busbar 33, the first fingers 351 being connected to the first busbar 31 and spaced from the second busbar 33, the second fingers 353 being connected to the second busbar 33 and spaced from the first busbar 31. At least one of the plurality of second fingers 353 is a second bent finger 60, wherein the connection portion, intermediate portion, and main body portion of the second bent finger 60 correspond to the second connection portion 3531, the second intermediate portion 3533, and the second main body portion 3535 in the above embodiments. The first bent finger 50 and the second bent finger 60 are generally arranged in pairs and alternately spaced.

The specific structural design of IDT 30 and its beneficial effects can be understood with reference to the above embodiments and are not repeated herein.

The resonator 1 provided in the embodiments of the present application, compared with conventional TC-SAW resonators, differs in that conventional TC-SAW resonators generally set piston structures (fingers widened and/or thickened) within the working area (overlapping region). Due to process limitations, the presence of these piston structures can restrict the width of the fingers or the spacing between two adjacent fingers, thereby limiting the operating frequency range of the resonator. In contrast, the resonator 1 of the present embodiments can suppress spurious modes simply by changing the shape of the fingers 35, eliminating the need to provide piston structures in the working area. This effectively avoids the limitations that piston structures impose on the operating frequency range of the resonator 1, allowing either an increase in operating frequency or, at the same frequency, a reduction in the size of the resonator 1.

In the IDT 30 of the present embodiments, since the connection portion and the intermediate portion of the bent finger are arranged at an angle, and the main body portion and the intermediate portion are arranged at an angle, an opening directed away from the connection portion is formed between the intermediate portion, connection portion, and busbar. A distance difference exists along the acoustic wave propagation direction between the connection portion and the main body portion, and a gap is formed between the intermediate portion of one electrode assembly and the main body portion of the other electrode assembly. By configuring these distance differences, angles, gaps, and openings in the bent finger 30 structure, the intensity of the excitation source in the gap region can be reduced, thereby suppressing secondary excitation of the excitation source and reducing stray acoustic waves. As a result, not only can lateral spurious modes be suppressed, but spurious modes generated in the gap region can also be effectively suppressed. Moreover, compared with an IDT lacking the above features, the IDT 30 of the present embodiments can achieve enhanced suppression of spurious modes.

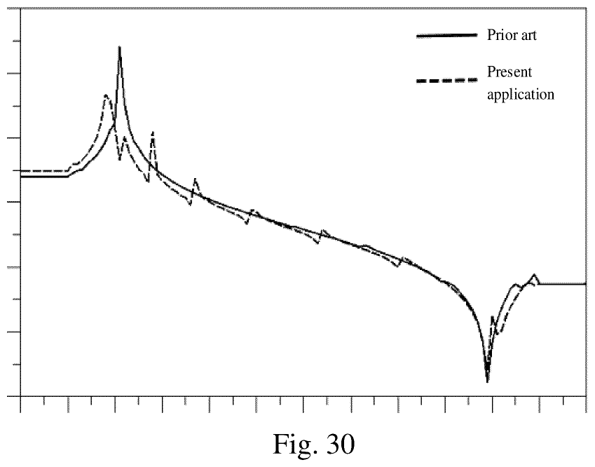

Please refer to FIG. 30. In FIG. 30, the horizontal axis represents the acoustic wave frequency, and the vertical axis represents admittance. The solid line represents the resonator 1 in the embodiments of the present application, which does not use piston structures but employs a bent finger structure. The dashed line represents a conventional TC-SAW resonator in the prior art, which neither employs a bent finger structure nor a piston structure in the working area. As can be seen from the figure, the resonator 1 of the present embodiments exhibits a smoother admittance curve compared with the conventional TC-SAW resonator. Sharp spurious waves or peaks in the admittance curve become more flattened. Therefore, compared with the conventional TC-SAW resonator that does not include piston structures, the resonator 1 provided by the present embodiments can effectively suppress spurious modes. Moreover, it can be observed from the Fig. that the main resonance peak of the resonator 1 in the present embodiments is higher than that of the conventional resonator, which can increase the Q factor.

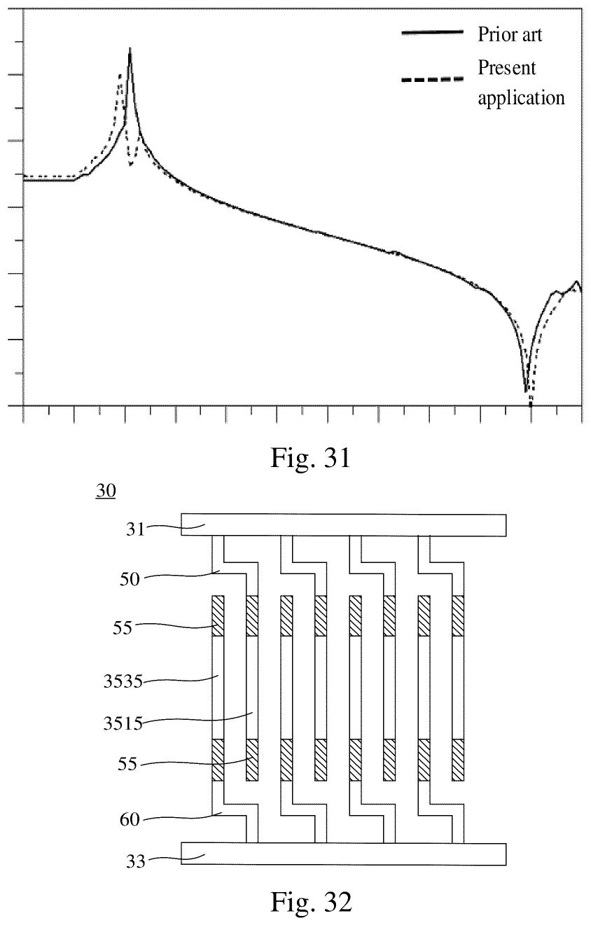

Please refer to FIG. 31. In FIG. 31, the horizontal axis represents the acoustic wave frequency, and the vertical axis represents admittance. The solid line represents the resonator 1 in the present embodiments, which does not use piston structures but employs a bent finger structure. The dashed line represents a conventional TC-SAW resonator, which does not employ a bent finger structure but does include piston structures in the working area. As can be seen from the figure, in the conventional TC-SAW resonator, acoustic waves at the main resonance peak can couple with spurious modes (lateral waves or spurious waves), as indicated on the right side of the peak in the dashed line. This shows that the spurious mode suppression effect of the conventional resonator is not ideal. In contrast, the resonator 1 of the present embodiments forms a relatively smooth curve between the main resonance peak and the adjacent valleys (as shown by the solid line in FIG. 31), effectively resolving coupling with spurious modes and thereby effectively suppressing them. Furthermore, comparing the main resonance peaks shown by the solid and dashed lines in FIG. 31, it can be seen that the main resonance peak of the present embodiment (solid line) is higher than that of the conventional resonator, indicating an improved Q factor. Therefore, compared with conventional TC-SAW resonators that include piston structures in the working area, the resonator 1 provided in the present embodiments can suppress spurious modes and enhance the Q factor simply by changing the shape of finger 35, without the need to provide piston structures in the working area.

In some embodiments, the temperature compensation layer 70 is used to adjust the temperature coefficient of frequency of the resonator 1, so as to prevent changes in the resonance frequency of the resonator 1 caused by temperature variations. The temperature compensation layer 70 may have a positive temperature coefficient to compensate for the negative temperature coefficient of the piezoelectric substrate 10. The material of the temperature compensation layer 70 includes, but is not limited to, silicon dioxide, fluorinated silicon dioxide, and silicon nitride-based silicon dielectric films. In the embodiments of the present application, the thickness of the temperature compensation layer 70 can be adjusted as needed to balance the values of the Q factor, frequency temperature coefficient, and electromechanical coupling coefficient.

In some embodiments, the temperature compensation layer 70 is located in the region between the two busbars (the first busbar 31 and the second busbar 33) and covers the surfaces of multiple fingers 35. That is, the temperature compensation layer 70 may be positioned between the two busbars and cover the multiple fingers 35 and the piezoelectric substrate 10 located between the two busbars. This configuration can improve the Q factor of the resonator 1.

In other embodiments, in addition to covering the surfaces of multiple fingers 35, the temperature compensation layer 70 may also cover the two busbars. Specifically, it may cover one busbar or both busbars, and may cover part or all of the busbar. The present application is not limited in this respect.

In some embodiments, the resonator 1 may further include a frequency tuning layer 90. The frequency tuning layer 90 may be arranged on the surface of the temperature compensation layer 70 opposite to the IDT 30, and may be used to adjust the resonance frequency of the resonator 1.

The frequency tuning layer 90 may be made of silicon nitride, silicon oxynitride, or other suitable materials. The frequency tuning layer 90 may be a single layer or a multilayer structure, and different materials may be used between layers. The frequency tuning layer 90 can be used to adjust the resonance frequency of the resonator 1, and may also serve as a passivation layer to protect the IDT 30, helping to prevent damage or corrosion of the IDT 30.

In some embodiments, the electrode assemblies may be formed of conductive materials. That is, the first busbar 31, the second busbar 33, and the fingers 35 may be made of conductive materials such as metallic materials including aluminum, molybdenum, copper, gold, platinum, silver, nickel, chromium, tungsten, and the like. The electrode assemblies may have a single-layer or multilayer structure, and the materials of different layers may be the same or different. The present application is not limited in this respect.

In some embodiments, the overlap area may be a central area.

Referring to FIGS. 6 and 7, in some embodiments, the first connection portion 3511 and the first main body portion 3515 may be connected to any position of the first intermediate portion 3513 in a staggered manner. Specifically, the first connection portion 3511 and the first main body portion 3515 are not overlapped in the Y direction. Similarly, the second connection portion 3531 and the second main body portion 3535 may also be connected to any position of the second intermediate portion 3533 in a staggered manner, and details thereof will not be repeated herein. The Y direction refers to the direction from the first busbar 31 toward the second busbar 33.

It should be noted that, in the embodiments of the present application, the first connection portion 3511 and the first main body portion 3515 are not overlapped in the Y direction, and the second connection portion 3531 and the second main body portion 3535 are also not overlapped in the Y direction. Compared with the structure in which the first connection portion 3511 and the first main body portion 3515 are overlapped in the Y direction and the second connection portion 3531 and the second main body portion 3535 are overlapped in the Y direction, the non-overlapping configuration can more effectively suppress spurious modes and improve the Q factor.

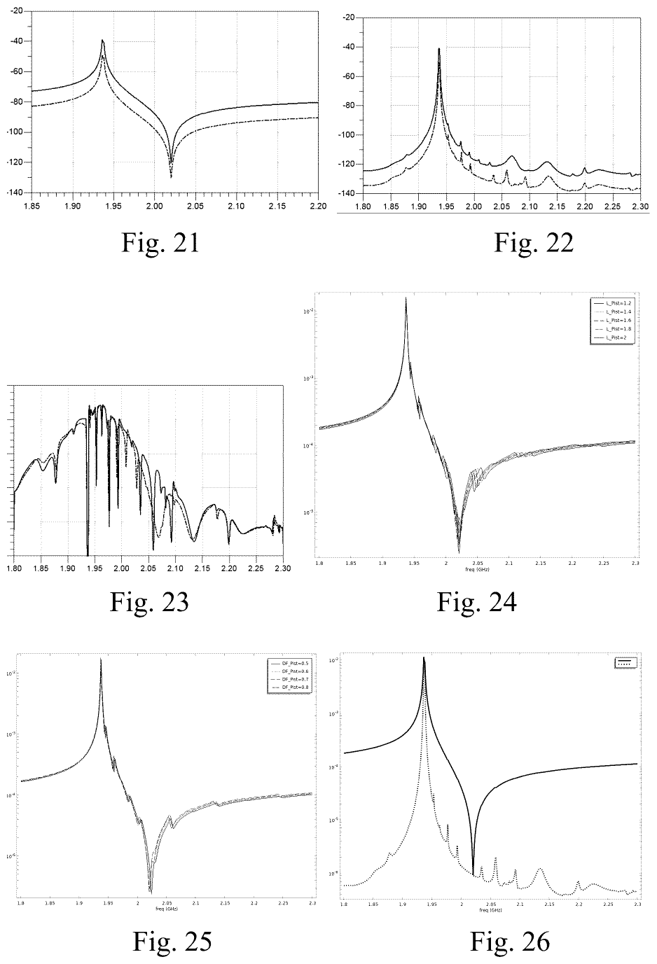

Referring to FIGS. 21 to 23, FIG. 21 shows a comparison curve of frequency versus admittance between the resonator of the related art and the resonator 1 of the present application. FIG. 22 shows a comparison curve of frequency versus the real part of admittance between the resonator of the related art and the resonator 1 of the present application. FIG. 23 shows a comparison curve of the Q factor between the resonator of the related art and the resonator 1 of the present application. In these figures, the dashed line represents the resonator of the related art, in which the connection portion and the main body portion of the same finger overlap in the Y direction. The solid line represents the resonator 1 of the present application, in which the connection portion and the main body portion of the same finger do not overlap in the Y direction. As can be seen from FIGS. 21 to 23, the resonator of the present application exhibits better spurious mode suppression performance than the resonator of the related art and can improve the Q factor to a certain extent.

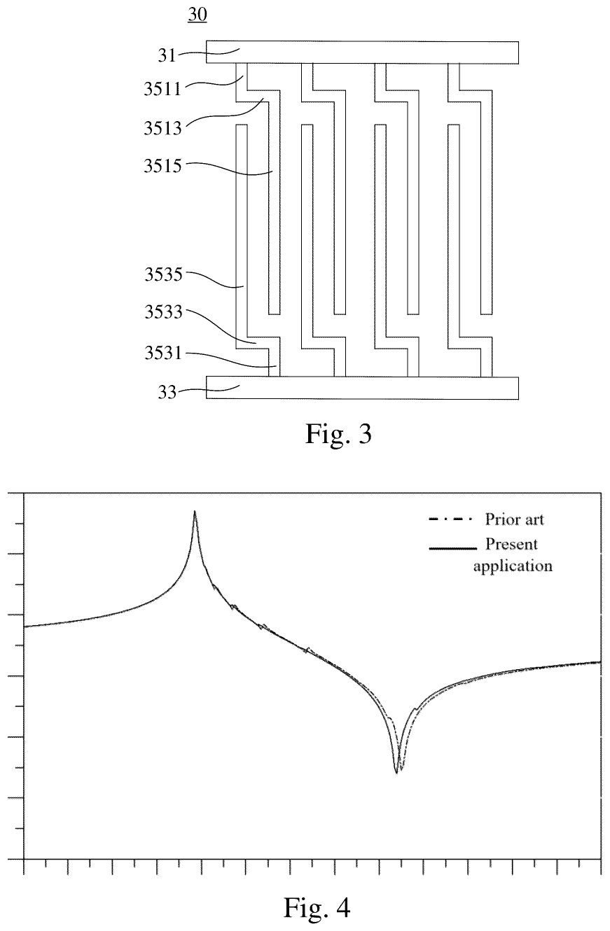

As shown in FIGS. 3 and 14, as an example, the ends of the first connection portion 3511 and the first main body portion 3515 may be respectively connected to the two ends of the first intermediate portion 3513. Similarly, the ends of the second connection portion 3531 and the second main body portion 3535 may be respectively connected to the two ends of the second intermediate portion 3533.

As shown in FIG. 7, as another example, the ends of the first connection portion 3511 and the first main body portion 3515 may be respectively connected to positions between the two ends of the first intermediate portion 3513. Similarly, the ends of the second connection portion 3531 and the second main body portion 3535 may also be respectively connected to positions between the two ends of the second intermediate portion 3533. It can be understood that the ends of the first intermediate portion 3513 extend beyond the first main body portion 3515 in the Y direction, such that two adjacent first intermediate portions 3513 have a very small gap. Similarly, two adjacent second intermediate portions 3533 may also have a very small gap.

As another example, an end of the first connection portion 3511 may be connected to an end of the first intermediate portion 3513, and an end of the first main body portion 3515 may be connected to a position between the two ends of the first intermediate portion 3513. Similarly, an end of the second connection portion 3531 may be connected to an end of the second intermediate portion 3533, and an end of the second main body portion 3535 may be connected to a position between the two ends of the second intermediate portion 3533.

As shown in FIG. 6, as another example, an end of the first main body portion 3515 may be connected to an end of the first intermediate portion 3513, and an end of the first connection portion 3511 may be connected to a position between the two ends of the first intermediate portion 3513. Similarly, an end of the second main body portion 3535 may be connected to an end of the second intermediate portion 3533, and an end of the second connection portion 3531 may be connected to a position between the two ends of the second intermediate portion 3533.

In these examples, the end of the first connection portion 3511 refers to the end of the first connection portion 3511 away from the first busbar 31, and the end of the first main body portion 3515 refers to the end of the first main body portion 3515 facing toward the first busbar 31. The end of the second connection portion 3531 refers to the end of the second connection portion 3531 away from the second busbar 33, and the end of the second main body portion 3535 refers to the end of the second main body portion 3535 facing toward the second busbar 33.

In some embodiments, the resonator 1 may further include reflectors, which may be arranged on the piezoelectric substrate 10. The number of reflectors may be two, and the two reflectors may be respectively located at both ends of the IDT 30 along the propagation direction of the acoustic wave. That is, the two reflectors are oppositely arranged at both ends of the IDT 30 along the X direction, such that the reflectors at both ends can reflect the acoustic waves generated by the resonator 1, thereby helping to confine the acoustic waves between the two reflectors.

For ease of description, the region along the X direction between the first busbar 31 and the end of the second main body portion 3535 is referred to as the first gap region, and the region along the X direction between the second busbar 33 and the end of the first main body portion 3515 is referred to as the second gap region.

In some embodiments, the first busbar 31 and the second busbar 33 may be parallel to the propagation direction of the acoustic wave (X direction). Alternatively, the first busbar 31 and the second busbar 33 may be inclined relative to the propagation direction of the acoustic wave, and the inclination directions of the two busbars may be the same or different. Compared with the configuration where the busbars are parallel to the propagation direction of the acoustic wave, the inclined arrangement can better suppress spurious modes. In other words, the extending direction of the busbars forms an angle with the propagation direction of the acoustic wave. The inclination directions of the first busbar 31 and the second busbar 33 may be the same or different.

In other embodiments, the first busbar 31 and the second busbar 33 may have a shape that is wider in the middle and narrower on both sides. The embodiments of the present application are not limited thereto.

In some embodiments, the thicknesses of the first connection portion 3511 and the first main body portion 3515 may both be smaller than the thickness of the first intermediate portion 3513, and the thicknesses of the second connection portion 3531 and the second main body portion 3535 may both be smaller than the thickness of the second intermediate portion 3533. The thicknesses of the main body portions (the first main body portion 3515 and the second main body portion 3535), the connection portions (the first connection portion 3511 and the second connection portion 3531), and the intermediate portions (the first intermediate portion 3513 and the second intermediate portion 3533) may also be the same, and the present application is not limited thereto. In addition, when the thickness of the intermediate portions is greater than that of the connection portions and the main body portions, compared with the structure in which the connection portions, main body portions, and intermediate portions have the same thickness, spurious modes can be further suppressed, the Q factor can be improved, and thus the operating performance of the resonator 1 can be enhanced.

In some embodiments, the thicknesses of the first connection portion 3511, the second connection portion 3531, the first main body portion 3515, and the second main body portion 3535 are defined as “a”, and the thicknesses of the first intermediate portion 3513 and the second intermediate portion 3533 are defined as “b”, where a≤b. When a and b satisfy the above relationship, spurious modes can be better suppressed.

In some embodiments, the widths of the first intermediate portion 3513 and the second intermediate portion 3533 along the direction from the first busbar 31 toward the second busbar 33 may be greater than the widths of the first main body portion 3515 and the second main body portion 3535 along the propagation direction of the acoustic wave. On the basis that the fingers deform in the gap regions (the first gap region and the second gap region), this configuration can further suppress spurious modes, improve the Q factor, and thereby enhance the operating performance of the resonator 1.

In addition, compared with resonators in the related art that suppress spurious modes by providing a piston structure in the active region, the resonator 1 provided in the embodiments of the present application achieves suppression of spurious modes by varying the shape of the fingers in the gap regions, thereby reducing manufacturing complexity and, under the same processing conditions, enabling an increase in the resonant frequency of the resonator 1 or a reduction in its size.

The resonator 1 provided in the embodiments of the present application may further suppress spurious modes by designing parameters related to the first finger 351 and the second finger 353, as detailed below.

In some embodiments, the widths of the first intermediate portion 3513 and the second intermediate portion 3533 along the direction from the first busbar 31 toward the second busbar 33 are defined as L1. When the resonator 1 is a conventional surface acoustic wave resonator, L1 may be defined within the range of 0.1λ≤L1≤0.4λ. By taking into account both the spurious mode suppression effect and the influence of the resistance value of the intermediate portions, defining the intermediate portions within this range can further enhance the performance of the resonator 1. In the embodiments of the present application, based on varying the shapes of the first finger 351 and the second finger 353, by further defining the width ranges of the first intermediate portion 3513 and the second intermediate portion 3533 along the X direction, spurious modes can be more effectively suppressed. The widths of the first intermediate portion 3513 and the second intermediate portion 3533 may be the same or different, and the present application is not limited thereto.

Where λ represents the wavelength of the acoustic wave, the wavelength may correspond to the center-to-center distance between two adjacent first fingers 351, or the center-to-center distance between two adjacent second fingers 353. Alternatively, the wavelength may be twice the center-to-center distance between an adjacent first finger 351 and second finger 353.

For example, the width of the first intermediate portion 3513 along the Y direction may be 0.1λ, 0.2λ, 0.3λ, 0.4λ, and so on; similarly, the width of the second intermediate portion 3533 along the Y direction may be 0.1λ, 0.2λ, 0.3λ, 0.4λ, and so on.

In some embodiments, the width of the first intermediate portion 3513 along the Y direction and the width of the second intermediate portion 3533 along the Y direction may be equal or different.

In some embodiments, when the resonator 1 is a piezoelectric thin film SAW resonator, the width L1 may be defined such that λ≥L1≥0.1λ. By considering both the spurious mode suppression effect and the influence of the resistance value of the intermediate portions, defining the intermediate portions within this range can further enhance the performance of the piezoelectric thin film SAW resonator.

For example, the widths of the first intermediate portion 3513 and the second intermediate portion 3533 along the direction from the first busbar 31 toward the second busbar 33 may be 0.1λ, 0.2λ, 0.5λ, 0.75λ, λ, and so on.

In some embodiments, when the resonator 1 is a piezoelectric thin film SAW resonator, L1 may be further defined within the range of 0.25λ≥L1≥0.175λ, thereby further suppressing spurious modes. For example, the widths of the first intermediate portion 3513 and the second intermediate portion 3533 may be 0.175λ, 0.18λ, 0.2λ, 0.22λ, 0.25λ, and so on.

In some embodiments, when the resonator 1 is a TC-SAW resonator, L1 may be defined within the range of 0.15λ≤L1≤0.5λ. When L1 is within this range, the IDT 30 can more effectively suppress spurious modes. Specifically, L1 may be 0.15λ, 0.2λ, 0.3λ, 0.4λ, 0.5λ, and so on.

In some embodiments, when the resonator 1 is a TC-SAW resonator, L1 may be further defined within the range of 0.2λ≤L1≤0.35λ. When L1 is within 0.2λ to 0.35λ, the IDT 30 can further suppress spurious modes. Specifically, L1 may be 0.2λ, 0.25λ, 0.3λ, 0.35λ, and so on.

It should be noted that the width of the first intermediate portion 3513 in the direction from the first busbar 31 toward the second busbar 33 may refer to the actual width of the first intermediate portion 3513 itself, or the projected width of the first intermediate portion 3513 in the X direction. Similarly, the width of the second intermediate portion 3533 in the direction from the first busbar 31 toward the second busbar 33 may refer to the actual width of the second intermediate portion 3533 itself, or the projected width of the second intermediate portion 3533 in the X direction.

In some embodiments, the duty ratios of the first finger 351 and the second finger 353 may both be defined as DF. When the resonator 1 is a conventional surface acoustic wave resonator, DF may be defined within the range of 0.3≤DF≤0.6. In the present application, based on the modified shapes of the first finger 351 and the second finger 353, setting the duty ratio of the fingers (the first finger 351 and the second finger 353) within this range can further reduce spurious acoustic waves and help further suppress spurious modes.

For example, the duty ratio of the first finger 351 may be 0.3, 0.4, 0.53, 0.6, and so on.

The duty ratio of the second finger 353 may also be 0.3, 0.4, 0.53, 0.6, and so on.

The duty ratio refers to the ratio of the width of the finger 35 in the X direction (the propagation direction of the acoustic wave) to the center-to-center distance between two adjacent fingers 35 in the overlapping region. It can be understood that this range may also be considered as the duty ratio range of the IDT 30.

In some embodiments, when the resonator 1 is a piezoelectric thin-film SAW resonator, DF may be defined within the range of 0.6≥DF≥0.25. In the present application, based on the modified shapes of the first finger 351 and the second finger 353, setting the duty ratio of the fingers within this range can further reduce spurious acoustic waves and help suppress spurious modes.

For example, the duty ratios of both the first finger 351 and the second finger 353 may be 0.25, 0.38, 0.4, 0.43, 0.6, and so on.

In some embodiments, DF may be further defined within the range of 0.55≥DF≥0.3, thereby further suppressing spurious modes. For example, the duty ratios of both the first finger 351 and the second finger 353 may be 0.3, 0.38, 0.4, 0.43, 0.55, and so on.

In some embodiments, when the resonator 1 is a piezoelectric thin-film SAW resonator, the electrode thickness ratio of the resonator 1 may be defined as e, where 0.09≥e≥0.07. In the present application, based on the modified shapes of the first finger and the second finger, defining the electrode thickness ratio of the resonator 1 within this range can more effectively suppress spurious modes.

For example, the electrode thickness ratio of the resonator 1 may be 0.07, 0.075, 0.08, 0.087, 0.09, and so on.

The film thickness ratio of the resonator 1 may refer to the ratio of the thickness of the finger 35 to the wavelength of the acoustic wave. The thickness direction of the finger 35 may be the direction from the first dielectric layer 40 toward the piezoelectric substrate 10. In the embodiments of the present application, the film thickness ratio may be defined as the ratio of the thickness of the first finger 351 or the second finger 353 to the wavelength. Optionally, the film thickness ratio may also refer to the ratio of the thickness of the first main body portion 3515 or the second main body portion 3535 to the wavelength. In general, the thicknesses of the first main body portion 3515 and the second main body portion 3535 are approximately equal.

In some embodiments, the duty ratio of the first finger 351 and that of the second finger 353 may be equal.

In some embodiments, whether the resonator 1 is a conventional surface acoustic wave resonator or a TC-SAW resonator, the length of the first intermediate portion 3513 and the second intermediate portion 3533 along the propagation direction of the acoustic wave may be defined as W1, satisfying the following condition:

$$( 1 + DF ) * \frac{λ}{2} \leq W 1 < λ .$$

When W1 and DF satisfy the above relationship, spurious modes can be more effectively suppressed.

In the present application, in the acoustic wave propagation direction, the distance between two adjacent intermediate portions (the first intermediate portion 3513 and the second intermediate portion 3533) within the same electrode assembly may be reduced to the process limit so that they remain unconnected. Specifically, the length of the intermediate portion along the acoustic wave propagation direction may be smaller than X, for example, (λ−0.1) μm. Under the same process constraints, the center-to-center distance between adjacent main body portions may no longer be limited by the piston structure (widened fingers), allowing the center-to-center distance between adjacent main body portions (the first main body portion 3515 and the second main body portion 3535) to be smaller than that in resonators having a piston structure (widened fingers) in the related art. Alternatively, the width of the main body portion may not be restricted by the piston structure (thickened fingers), allowing the width of the main body portion to be smaller than that in resonators with a piston structure (thickened fingers) in the related art. Consequently, the resonant frequency of the resonator 1 can be increased, or the size of the resonator 1 can be reduced at the same resonant frequency.

In some embodiments, the length of the first intermediate portion 3513 along the acoustic wave propagation direction and the length of the second intermediate portion 3533 along the acoustic wave propagation direction may be equal or different. That is, the length of the first intermediate portion 3513 along the X direction and the length of the second intermediate portion 3533 along the X direction may be equal or different.

In some embodiments, the widths of the first gap 355 and the second gap 357 are defined as L2. When the resonator 1 is a conventional surface acoustic wave (SAW) resonator, L2 can be limited to 0.1λ≤L2≤0.8λ. When L2 is within this range, spurious mode suppression can be improved.

For example, the width of the first gap 355 can be 0.1λ, 0.2λ, 0.5λ, 0.8λ, etc. Similarly, the width of the second gap 357 can be 0.1λ, 0.2λ, 0.5λ, 0.8λ, etc.

In some embodiments, when the resonator 1 is a piezoelectric thin-film SAW resonator, L2 can be limited to 1.15λ≥L2≥0.125λ. In the present application, based on the modification of the first finger 351 and the second finger 353, limiting the widths of the first gap 355 and the second gap 357 within this range can further improve spurious mode suppression. The widths of the first gap 355 and the second gap 357 may be the same or different.

For example, the widths of the first gap 355 and the second gap 357 may each be 0.125λ, 0.5λ, 0.82λ, λ, 1.15λ, etc.

In some embodiments, when the resonator 1 is a TC-SAW resonator, L2 can be limited to 0.125λ≤L2≤1.15λ. In the present application, based on the use of bent fingers 331, limiting the widths of the gaps (the first gap 355 and the second gap 357) within this range can further improve spurious mode suppression. Specifically, L2 can be 0.15λ, 0.2λ, 0.3λ, 0.5λ, 0.8λ, λ, etc.

In some embodiments, when the resonator 1 is a TC-SAW resonator, L2 can be further limited to 0.125λ≤L2≤0.2λ. Specifically, if L2 is too large, the resonance points of the acoustic wave may couple with spurious modes, resulting in poor spurious mode suppression. Generally, the smaller the value of L2, the better the IDT 30 suppresses spurious modes. When L2 is within the range of 0.125λ to 0.2λ, it can satisfy current manufacturing processes while enhancing the IDT 30's spurious mode suppression. Specifically, L2 can be 0.15λ, 0.18λ, 0.2λ, etc.

In some embodiments, the first gap 355 can be the perpendicular distance from the end of the second main body portion 3535 to the first intermediate portion 3513, and the second gap 357 can be the perpendicular distance from the first main body portion 3515 to the second intermediate portion 3533.

In some embodiments, whether for conventional surface acoustic wave resonators or piezoelectric thin-film SAW resonators, the widths of the first gap 355 and the second gap 357, L2, can also satisfy: 2 μm≥L2≥0.1 μm. This can further improve spurious mode suppression.

For example, the widths of the first gap 355 and the second gap 357 can be 0.1 μm, 0.8 μm, 1.4 μm, 2 μm, etc.

In some embodiments, the widths of the first gap 355 and the second gap 357 may be equal or different.

In some embodiments, the distances from the first busbar 31 to the first intermediate portion 3513 and from the second busbar 33 to the second intermediate portion 3533 are defined as L3. When the resonator 1 is a piezoelectric thin-film SAW resonator, L3 can be limited to 3λ≥L3≥0.125λ. In the present application, based on the modification of the first and second fingers, limiting the distance from the busbar to the intermediate portion within this range can better suppress energy leakage.

For example, the distance from the first busbar 31 to the first intermediate portion 3513 and the distance from the second busbar 33 to the second intermediate portion 3533 can be 0.125λ, 0.7λ, 1.8λ, 2.1λ, 3λ, etc.

It should be noted that the distance from the first busbar 31 to the first intermediate portion 3513 can refer to the projection length of the first connection portion 3511 in the X direction, or it can refer to the extension length of the first connection portion 3511 from the first busbar 31 toward the second busbar 33. Similarly, the distance from the second busbar 33 to the second intermediate portion 3533 can refer to the projection length of the second connection portion 3531 in the X direction, or it can refer to the extension length of the second connection portion 3531 from the second busbar 33 toward the first busbar 31.

In some embodiments, when the resonator 1 is a TC-SAW resonator, L3 can be limited to λ≤L3≤2.5λ. When L3 is within this range, the Q factor of the resonator 1 can be improved. Specifically, L3 can be λ, 1.2λ, 1.5λ, 1.8λ, 2.2λ, 2.5λ, etc.

In some embodiments, L3 can be further limited to 2λ≥L3≥λ to further suppress spurious modes. When L3 is within this range, the Q factor of the resonator 1 can be further enhanced. Specifically, if L3 is too small, the acoustic waves may easily leak from the region where the connection portion is located to the region of the busbar or even beyond the busbar, causing lateral acoustic loss and reducing the Q factor. When L3 is within λ to 2λ, the acoustic waves are less likely to leak outward through the region where the connection portion is located, thereby improving the Q factor of the resonator 1.

For example, the distance from the first busbar 31 to the first intermediate portion 3513 and the distance from the second busbar 33 to the second intermediate portion 3533 can be λ, 1.2λ, 1.5λ, 1.75λ, 1.8λ, 2λ, etc.

In some embodiments, L1+L2≤λ, so that when L1 and L2 satisfy the above formula, spurious modes can be better suppressed.

Specifically, the width of the first intermediate portion 3513 along the direction from the first busbar 31 to the second busbar 33 is L1, and the width of the first gap 355 is L2, with L1+L2≤λ. Similarly, the width of the second intermediate portion 3533 along the direction from the first busbar 31 to the second busbar 33 is L1, and the width of the second gap 357 is L2, with L1+L2≤λ.

When the resonator 1 is a TC-SAW resonator, the resonator 1 according to the present embodiment can also be designed to define the relationship among L1, L2, and L3 to further enhance the IDT 30's suppression of spurious modes and improve the Q factor. In some embodiments, L1+L2≤L3, and λ≤L1+L2+L3≤3.5λ.

In some embodiments, the distance from the first busbar 31 to the first intermediate portion 3513 is greater than the width of the first gap 355, and the distance from the second busbar 33 to the second intermediate portion 3533 is greater than the width of the second gap 357. Compared with the case where the distance from the first busbar 31 to the first intermediate portion 3513 is less than or equal to the width of the first gap 355, and the distance from the second busbar 33 to the second intermediate portion 3533 is less than or equal to the width of the second gap 357, this configuration can better suppress spurious modes.

The distance between the first busbar 31 and the first intermediate portion 3513 can approximately refer to the projection length of the first connection portion 3511 in the X direction, or it can refer to the extension length of the first connection portion 3511 from the first busbar 31 toward the second busbar 33. Similarly, the distance between the second busbar 33 and the second intermediate portion 3533 can approximately refer to the projection length of the second connection portion 3531 in the X direction, or it can refer to the extension length of the second connection portion 3531 from the second busbar 33 toward the first busbar 31.

In some embodiments, the distance between the two ends of the first intermediate portion 3513 or the two ends of the second intermediate portion 3533 along the direction from the first busbar 31 to the second busbar 33 is defined as L, where L=λ·A, and 0≤A≤0.3. This arrangement helps further suppress spurious modes.

It should be noted that L can be the projection distance in the X direction between the two ends of the first intermediate portion 3513, or it can be the projection distance in the X direction between the two ends of the second intermediate portion 3533.

In some embodiments, when A=0, the first intermediate portion 3513 is parallel to the propagation direction of the acoustic wave, and the second intermediate portion 3533 is also parallel to the propagation direction of the acoustic wave. It can be understood that when A>0, L>0, the extension direction of the first intermediate portion 3513 forms an angle with the X direction. In this case, either end of the first intermediate portion 3513 along the X direction can be closer to the first busbar 31; this is not limited in the present application.

In some embodiments, the angle between the first intermediate portion 3513 and the first main body portion 3515 can be a right angle, an acute angle, or an obtuse angle.

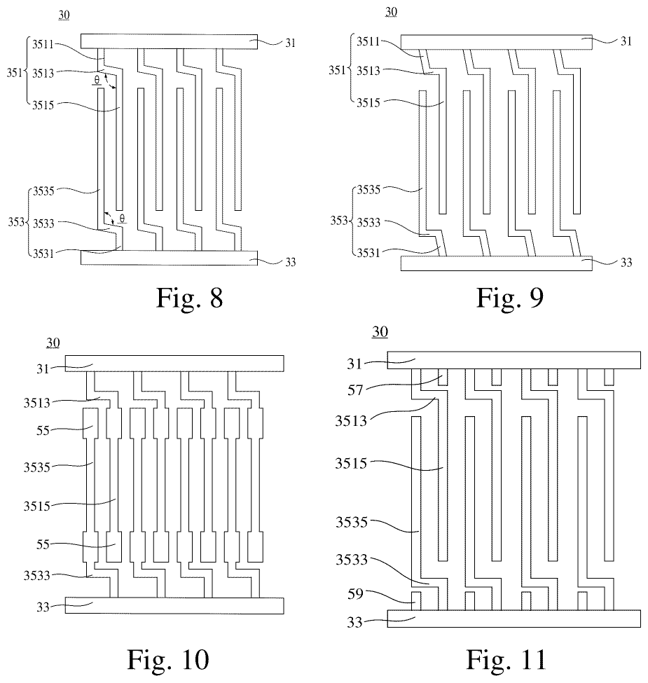

Specifically, with reference to FIG. 8, in some embodiments, the angle between the first intermediate portion 3513 and the first main body portion 3515, as well as the angle between the second intermediate portion 3533 and the second main body portion 3535, is denoted as θ, and

$$θ = 90 ° + arcsin ( 2 A / \sqrt{1 + 4 * {A}^{2}} )$$

where 0≤A≤0.3.

In some feasible embodiments, 60°≤θ≤120°; in certain embodiments, 90°≤θ≤118°. Within this range, the IDT 30 can better suppress spurious modes.

With reference to FIG. 9, in some embodiments, the first connection portion 3511 and the first busbar 31 can be connected perpendicularly or non-perpendicularly. For example, the angle between the first connection portion 3511 and the first busbar 31 can be greater than 0° and less than 90°. Specifically, a non-perpendicular connection between the first connection portion 3511 and the first busbar 31, compared to a perpendicular connection, can help further suppress spurious modes.

It can be understood that when the first connection portion 3511 is connected to the first busbar 31, two angles are formed between them, the sum of which is 180°. The above-mentioned angle being greater than 0° and less than 90° means that either of the two angles is greater than 0° and less than 90°.

In some embodiments, the angle between the second connection portion 3531 and the second busbar 33 is also greater than 0° and less than 90°. Descriptions regarding the connection of the second connection portion 3531 to the second busbar 33 can refer to the corresponding description of the first connection portion 3511 and the first busbar 31, and are not repeated herein.

In some embodiments, the extension direction of the first connection portion 3511 and the first main body portion 3515 can be parallel or set at an angle relative to each other. Similarly, the extension direction of the second connection portion 3531 and the second main body portion 3535 can be parallel or set at an angle. This is not limited in the present application. By adjusting the angle between the connection portion and the main body portion of the same finger, spurious modes can be better suppressed.

With reference to FIG. 10, in some embodiments, the first main body portion 3515 and the second main body portion 3535 can each include a piston structure 55 in the overlapping region. The piston structure 55 is located on opposite sides of the overlapping region along the direction from the first busbar 31 to the second busbar 33. The piston structure 55 can include widened and/or thickened finger structures on opposite sides of the overlapping region along the first busbar 31 to the second busbar 33 direction. It is understood that the piston structure 55 can be arranged below the fingers, within the piezoelectric substrate 10, or above the fingers. The piston structure 55 can be made of discontinuous conductive material, or of continuous metal or non-metal material. The present application does not impose any limitation on this. The piston structure 55 increases the mass load in the corresponding region and reduces the acoustic velocity on opposite sides of the overlapping region along the Y direction, thereby forming a piston mode. In a configuration where the finger includes a connection portion, an intermediate portion, and a main body portion, arranging the piston structure 55 at the end regions of the main body portion can further reduce lateral acoustic wave loss and help suppress spurious modes.

Specifically, the first main body portion 3515 includes a first portion, a second portion, a third portion, and a fourth portion connected in sequence. The first portion is located in the first gap region, and the second, third, and fourth portions are located within the overlapping region. The second and fourth portions are at the opposite ends of the third portion. The second and fourth portions can each include a piston structure 55, meaning that the width of the second and fourth portions is greater than that of the third portion, or the thickness of the second and fourth portions is greater than that of the third portion, or both the width and thickness of the second and fourth portions are greater than those of the third portion. Generally, the width and thickness of the third portion can be approximately equal to or different from those of the first portion; the present application imposes no specific limitation on this.

In some embodiments, the first main body portion 3515 and the second main body portion 3535 each include a piston structure 55 in the overlapping region. The piston structure 55 is located on at least one side of the overlapping region along the direction from the first busbar 31 to the second busbar 33. Specifically, at least one of the second portion and the fourth portion can include the piston structure 55.

It is understood that the structure of the piston structure 55 on the second main body portion 3535 is substantially the same as that on the first main body portion 3515, and is not described in detail herein.

Referring to FIGS. 24 to 26, the horizontal axes of FIGS. 24 to 26 represent the frequency of the acoustic wave, and the vertical axes represent the admittance. FIG. 24 shows a frequency-admittance curve of an acoustic wave for a resonator in the prior art that employs a piston structure, where the IDT uses standard fingers, and a piston structure is formed on the standard fingers. As can be seen from FIG. 24, even by adjusting the length of the piston structure, the resonator in the prior art cannot effectively suppress lateral spurious modes. FIG. 25 shows a frequency-admittance curve of another resonator in the prior art that employs a piston structure, where the IDT also uses standard fingers, and a piston structure is formed on the standard fingers. From FIG. 25, it is evident that even by increasing the width of the ends of the standard fingers to form a piston structure and adjusting the duty ratio of the finger-end piston structure, the lateral spurious modes are still not well suppressed. Correspondingly, in the prior art, adjusting the thickness or width of the piston structure has a similar effect on spurious mode suppression and still cannot effectively suppress lateral spurious modes. FIG. 26 shows a frequency-admittance curve of the resonator 1 provided in the present application that includes the piston structure 55, where the fingers adopt a bent configuration. As can be clearly seen from the figure, the curve becomes smoother, indicating that lateral spurious modes are effectively suppressed. Therefore, by altering the shape of the first finger 351 within the first gap region and the shape of the second finger 353 within the second gap region, and by arranging the piston structure 55 on both sides of the overlapping region, the resonator 1 of the present application can not only better suppress lateral spurious modes of the acoustic wave, but also suppress spurious modes generated in the gap regions.

In addition, the resonator 1 provided in the embodiments of the present application can further suppress lateral spurious modes by designing the structural parameters of the piston structure 55, as described below.

In some embodiments, when the resonator 1 is a piezoelectric thin-film SAW resonator, the length of the piston structure 55 along the direction from the first busbar 31 to the second busbar 33 can be defined as f, where 2λ≥f≥0.1λ, thereby further helping to suppress lateral spurious modes.

For example, the length of the piston structure 55 along the direction from the first busbar 31 to the second busbar 33 can be 0.1λ, 0.8λ, λ, 1.6λ, 2λ, and so on.

In some embodiments, 0.8λ≥f≥0.3λ, thereby further suppressing spurious modes.

For example, the length of the piston structure 55 along the direction from the first busbar 31 to the second busbar 33 can be 0.3λ, 0.45λ, 0.6λ, 0.78λ, 0.8λ, and so on.

In some embodiments, the duty ratio of the piston structure 55 can be defined as DP, and the duty ratio of the first finger 351 or the second finger 353 can be defined as DF, where DP≥DF+0.25 and 0.6≥DF≥0.25. It should be noted that in this embodiment, the piston structure 55 specifically refers to the piston structure at the ends of the first finger 351 or second finger 353 in the overlapping region along the X direction, which is widened relative to the standard finger.

Compared with TC-SAW resonators in the prior art, in which a piston structure is provided in the working region, the prior art requires higher mass for the piston structure, which may cause coupling between the acoustic wave and spurious modes, thereby affecting the performance of the resonator.

In contrast, the resonator 1 provided in the embodiments of the present application, by adopting bent fingers to suppress spurious modes and arranging the piston structure 55 in the overlapping region, achieves a better suppression effect on spurious modes.

In some embodiments, the piston structure 55 can be configured to widen and/or thicken the finger. The piston structure 55 can also adopt a mass-loading bar.

Specifically, the piston structure can refer to thickening (as shown in FIG. 32) and/or widening (as shown in FIG. 10) the bent fingers located on both sides of the overlapping region. The mass-loading bar can be disposed on the surface of the IDT 30, such as the top surface or the bottom surface, or it can be disposed above the temperature compensation layer 70. It should be noted that, in this case, the mass-loading bar can be made of dielectric material. The mass-loading bar can also be disposed on the surface of the temperature compensation layer 70 opposite to the IDT 30, and the material of the mass-loading bar is not limited; it may be made of conductive material, dielectric material, or insulating material.

The resonator 1 provided in the embodiments of the present application can further suppress spurious modes by designing the relevant parameters of the piston structure 55.

Specifically, in some embodiments, when the resonator 1 is a TC-SAW resonator, the width of the piston structure 55 along the propagation direction of the acoustic wave can be defined as W2, where 0.1*λ/2≤W2≤DF*λ/2. Here, DF is the duty ratio of the bent finger, specifically the duty ratio of the main body portion of the bent finger in the overlapping region. When W2 satisfies the above formula, the IDT 30 can better suppress lateral spurious modes.

It should be noted that in this embodiment, the piston structure 55 specifically refers to the thickened portions of the bent fingers located on both sides of the overlapping region, as shown in FIG. 32.

In some embodiments, the piston structure 55 can also refer to the widened portions of the bent fingers located on both sides of the overlapping region. In this case, the width W2 of the piston structure 55 along the propagation direction of the acoustic wave can satisfy DF*λ/2≤W2≤0.7*λ/2, where DF is the duty ratio of the bent finger, specifically the duty ratio of the main body portion of the bent finger in the overlapping region. When W2 satisfies the above formula, the IDT 30 can better suppress lateral spurious modes.

Furthermore, the resonator 1 provided in the embodiments of the present application, by arranging the first intermediate portion 3513 and the second intermediate portion 3533, and by widening or thickening the first main body portion 3515 and the second main body portion 3535 located on both sides of the overlapping region, can further suppress lateral spurious modes, suppress spurious modes generated in the gap region, and improve the Q factor.

Referring to FIGS. 11 and 28, in some embodiments, the resonator 1 further includes a first dummy finger 57 and a second dummy finger 59. One end of the first dummy finger 57 is connected to the first busbar 31, and the other end is spaced apart from the first intermediate portion 3513. One end of the second dummy finger 59 is connected to the second busbar 33, and the other end is spaced apart from the second intermediate portion 3533. By providing the dummy fingers (first dummy finger 57 and second dummy finger 59), spurious modes can be more effectively suppressed, and energy leakage can be further reduced.

Specifically, the first dummy finger 57 can be located within the first gap region, positioned between the first intermediate portion 3513 and the first busbar 31. One end of the first dummy finger 57 is connected to the first busbar 31, and the other end is spaced from the first intermediate portion 3513. The second dummy finger 59 can be located within the second gap region, positioned between the second intermediate portion 3533 and the second busbar 33. One end of the second dummy finger 59 is connected to the second busbar 33, and the other end is spaced from the second intermediate portion 3533.

It can be understood that there is a spacing region between the dummy finger and the intermediate portion, which can form a high acoustic velocity region in this spacing. Compared with directly connecting the dummy finger to the intermediate portion, this arrangement can better suppress energy leakage.

In some embodiments, the first dummy finger 57 is variably weighted between the first busbar 31 and the second busbar 33, and the second dummy finger 59 is also variably weighted between the first busbar 31 and the second busbar 33.

The following explanation uses the first dummy finger 57 as an example; the weighting method of the second dummy finger 59 is substantially the same as that of the first dummy finger 57 and is not repeated herein.

Specifically, the length between the end of the first dummy finger 57 away from the first busbar 31 and the first busbar 31 can vary. When the length of the first dummy finger 57 changes, correspondingly, the distance of the first intermediate portion 3513 relative to the first busbar 31 changes along with the length of the first dummy finger 57, or the length of the first connection portion 3511 changes along with the length of the first dummy finger 57. Compared with the case without variable weighting, variably weighted dummy fingers can better suppress spurious modes, reduce energy leakage, and improve the Q factor.

Specifically, the length between the end of the first dummy finger 57 away from the first busbar 31 and the first busbar 31 can vary. When the lengths of multiple first dummy fingers 57 vary, the ends of these multiple first dummy fingers 57 can form regular or irregular patterns, such as wavy, zigzag, or other shapes; the dummy finger weighting is not limited to these shapes in the present application.

As an example, the length between the end of the first dummy finger 57 away from the first busbar 31 and the first busbar 31 can gradually increase from the middle of the busbar toward the two ends in the X direction. When the length of the first dummy finger 57 changes, the distance of the first intermediate portion 3513 relative to the first busbar 31 follows the change in the dummy finger length.

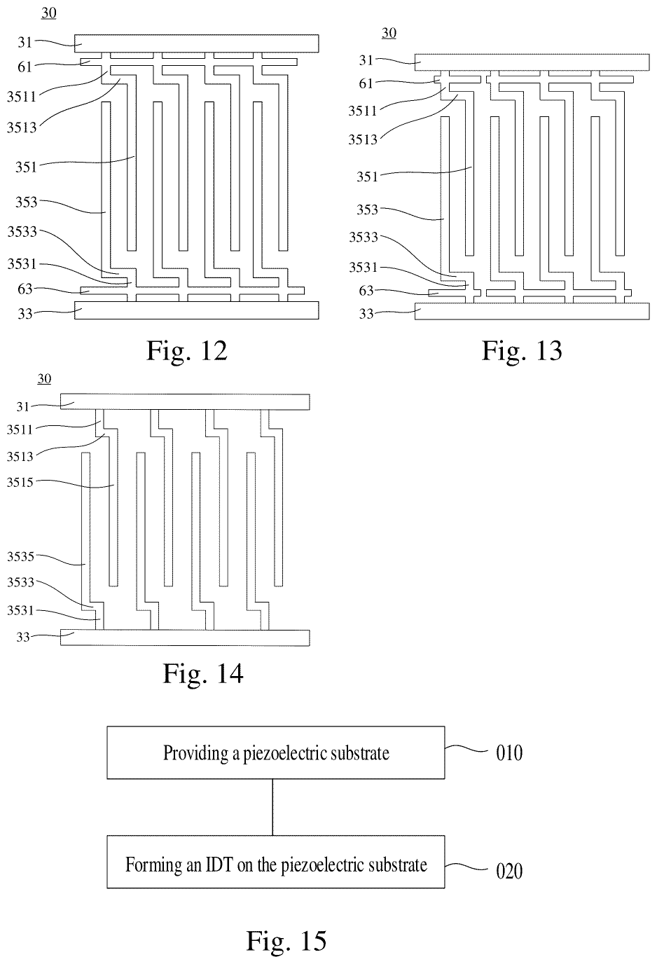

Referring to FIG. 12, in some embodiments, the resonator 1 may further include a first conductive strip 61, which can be disposed between the first intermediate portion 3513 and the first busbar 31, and is at least connected to the first connection portion 3511 of the first finger 351. A second conductive strip 63 can be disposed between the second intermediate portion 3533 and the second busbar 33, and is at least connected to the second connection portion 3531 of the second finger 353. The presence of the intermediate portion can introduce additional resistance, increasing device loss. By providing the conductive strips (the first conductive strip 61 and the second conductive strip 63), the resistance can be reduced, thereby reducing device loss.

The following explanation uses the first conductive strip 61 as an example; the structure and beneficial effects of the second conductive strip 63 are substantially the same as those of the first conductive strip 61 and are not repeated herein.

The first conductive strip 61 can be connected to one or more first connection portions 3511. For example, when the number of finger pairs 350 is one, the first conductive strip 61 can connect to the first connection portion 3511 of a single first finger 351. As another example, when the number of finger pairs 350 is multiple, the first conductive strip 61 can continuously connect to the first connection portions 3511 of each first finger 351 in each finger pair 350, i.e., the first conductive strip 61 extends in the X direction and connects each first connection portion 3511 uninterruptedly.

In some embodiments, the first conductive strip 61 may also extend in the X direction to continuously connect each finger 35 in the first gap region.

In some embodiments, the first conductive strip 61 can be spaced apart from the first busbar 31, and the first conductive strip 61 can be spaced apart from the first intermediate portion 3513.

In some embodiments, both the first conductive strip 61 and the second conductive strip 63 can be made of conductive metal or alloy, such as aluminum, molybdenum, copper, gold, platinum, silver, nickel, chromium, tungsten, etc. The first and second conductive strips 61, 63 may be made of the same metal or alloy as the IDT 30 and can be fabricated in the same process as the IDT 30, thereby reducing manufacturing steps.

Referring to FIG. 13, in some embodiments, the first conductive strip 61 may also be discontinuously disposed between the first intermediate portion 3513 and the first busbar 31, and the second conductive strip 63 may be discontinuously disposed between the second intermediate portion 3533 and the second busbar 33.

The following explanation uses the first conductive strip 61 as an example; the structure and beneficial effects of the second conductive strip 63 are substantially the same as those of the first conductive strip 61 and are not repeated herein.

The first conductive strip 61 can be connected to multiple first connection portions 3511. For example, when the number of finger pairs 350 is multiple, the first conductive strip 61 can discontinuously connect to the first connection portion 3511 of each first finger 351 in each finger pair 350. The first conductive strip 61 may be disconnected at the gaps between adjacent first connection portions 3511, or it may be disconnected after connecting multiple first connection portions 3511. This is not specifically limited in the present application.

In some embodiments, the first conductive strip 61 may also extend in the X direction to discontinuously connect to each finger 35 located in the first gap region.

In some embodiments, the width and length of the first conductive strip 61 and the second conductive strip 63 can be adjusted, which helps further tune the resistance and thereby reduce device loss.

Referring to FIGS. 1 to 3, in some embodiments, the first connection portion 3511 and the second main body portion 3535 can overlap in the direction from the first busbar 31 to the second busbar 33, and the second connection portion 3531 and the first main body portion 3515 can overlap in the same direction. Compared to configurations where the first connection portion 3511 and the second main body portion 3535 do not overlap along the Y direction, and the second connection portion 3531 and the first main body portion 3515 do not overlap along the Y direction, this configuration can better suppress lateral spurious modes of the acoustic wave.

Referring to FIGS. 7 and 14, in some embodiments, the first connection portion 3511 and the second connection portion 3531 can overlap in the direction from the first busbar 31 to the second busbar 33 and be positioned between the first main body portion 3515 and the second main body portion 3535. Compared to a configuration where the first connection portion 3511 overlaps the first main body portion 3515 along the Y direction, this embodiment can better suppress spurious modes.

In some embodiments, the first connection portion 3511 and the first main body portion 3515 can be connected to the two ends of the first intermediate portion 3513, which helps reduce the potential difference within the first gap region. As a result, the spurious mode potential distribution within the first gap region becomes more uniform, further aiding in the suppression of acoustic wave spurious modes.

In some embodiments, the second connection portion 3531 and the second main body portion 3535 can be connected to the two ends of the second intermediate portion 3533, which helps reduce the potential difference within the second gap region, making the potential distribution within the second gap region more uniform and further suppressing acoustic wave spurious modes.

In some embodiments, as shown in FIG. 16, the resonator 1 may further include a passivation layer 95. The passivation layer 95 covers the IDT 30 and can protect the IDT 30 from corrosion or damage. The passivation layer 95 may be made of materials such as silicon oxide or silicon nitride.

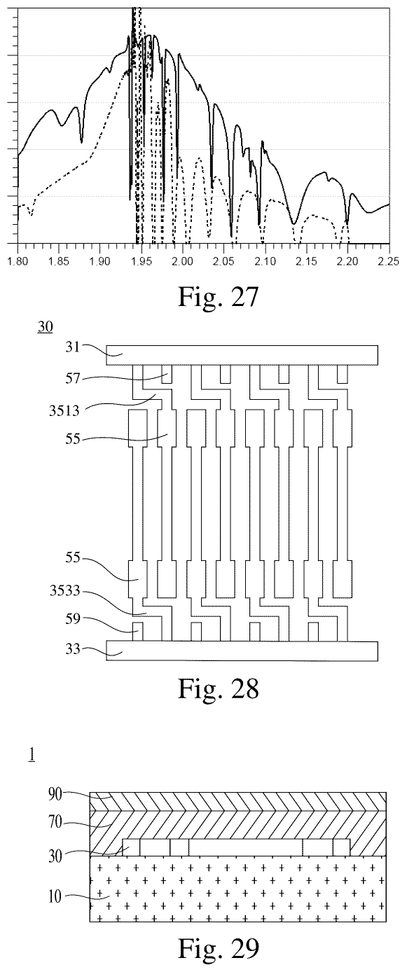

Referring to FIG. 27, the horizontal axis represents the acoustic wave frequency, and the vertical axis represents the Q factor. In FIG. 27, the dashed line represents a resonator of the prior art, and the solid line represents the resonator 1 provided in the present embodiment. It can be clearly seen that the Q factor of the solid line is significantly higher than that of the dashed line. Therefore, the resonator 1 provided in the present embodiment, by changing the shape of the first finger 351 between the end of the second finger 353 and the first busbar 31, and changing the shape of the second finger 353 between the end of the first finger 351 and the second busbar 33, can alter the spurious mode potential between the end of the second finger 353 and the first busbar 31, as well as the spurious mode potential between the end of the first finger 351 and the second busbar 33. This reduces the potential difference of spurious modes in the first gap region and the second gap region, making the potential distribution in both regions more uniform and thus suppressing spurious modes. Furthermore, the resonator 1 of the present embodiment can enhance the Q factor by designing parameters of the piezoelectric substrate 10, the first connection portion 3511, the first intermediate portion 3513, the first main body portion 3515, the second connection portion 3531, the second intermediate portion 3533, the second main body portion 3535, and the piston structures 55, thereby improving the operational performance of the resonator 1.

It can be understood that during the fabrication process, the shapes of the first finger and the second finger can be formed as metal conductive patterns on the piezoelectric substrate through processes such as photolithography, deposition, and etching. The present embodiment does not impose any limitation on this.

Referring to FIGS. 1 and 15, the present embodiment also provides a method for manufacturing the resonator 1, which includes steps S010 and S020.

Step S010: Providing a piezoelectric substrate 10.

Step S020: Forming an IDT 30 on the piezoelectric substrate 10.

The shape of the IDT 30, particularly the formation of the first finger 351 and the second finger 353, can be achieved through processes such as coating, exposure, development, deposition, and etching. The specific fabrication techniques can be found in the prior art and are not repeated herein.

The IDT 30 includes a first busbar 31 and a second busbar 33 disposed opposite each other on the piezoelectric substrate 10, and a plurality of finger pairs positioned between the first busbar 31 and the second busbar 33. At least one of the finger pairs 350 includes alternately spaced first fingers 351 and second fingers 353. The first finger 351 is connected to the first busbar 31 and spaced from the second busbar 33. The second finger 353 is connected to the second busbar 33 and spaced from the first busbar 31. The first finger 351 includes a first connection portion 3511, a first intermediate portion 3513, and a first main body portion 3515. The second finger 353 includes a second connection portion 3531, a second intermediate portion 3533, and a second main body portion 3535. The first main body portion 3515 and the second main body portion 3535 have an overlapping region along the propagation direction of the acoustic wave. The first connection portion 3511 is connected to the first busbar 31, and the first intermediate portion 3513 is positioned between the first connection portion 3511 and the first main body portion 3515, with a first gap 355 formed between the first intermediate portion 3513 and the end of the second main body portion 3535. The first connection portion 3511 and the first main body portion 3515 have a distance difference along the acoustic wave propagation direction. The first intermediate portion 3513 and the first main body portion 3515 are arranged at an angle. The first busbar 31, the first connection portion 3511, and the first intermediate portion 3513 are connected to form a first opening 37 facing away from the first connection portion 3511. The second connection portion 3531 is connected to the second busbar 33, and the second intermediate portion 3533 is positioned between the second connection portion 3531 and the second main body portion 3535, with a second gap 357 formed between the second intermediate portion 3533 and the first main body portion 3515. The second connection portion 3531 and the second main body portion 3535 have a distance difference along the acoustic wave propagation direction. The second intermediate portion 3533 and the second connection portion 3531 are arranged at an angle. The second busbar 33, the second connection portion 3531, and the second intermediate portion 3533 are connected to form a second opening 39, which faces opposite to the first opening 37.

Moreover, the design parameters and advantageous effects of the first busbar 31, the second busbar 33, the first connection portion 3511, the first intermediate portion 3513, the first main body portion 3515, the second connection portion 3531, the second intermediate portion 3533, the second main body portion 3535, and the piston structures 55 can be implemented with reference to the above-described embodiments, and are not repeated herein.

Referring to FIG. 1, the present embodiment also provides another resonator 1, in which the shapes of all fingers 35 are modified within the first gap region and the second gap region, thereby further improving the overall performance of the resonator 1.

Specifically, the resonator 1 includes a piezoelectric substrate 10 and an IDT 30. The IDT 30 is disposed on the piezoelectric substrate 10 and includes a first busbar 31 and a second busbar 33 oppositely arranged on the piezoelectric substrate 10, and a plurality of first fingers 351 and second fingers 353. The first fingers 351 and the second fingers 353 are alternately arranged. The first finger 351 is connected to the first busbar 31 and spaced from the second busbar 33, and the second finger 353 is connected to the second busbar 33 and spaced from the first busbar 31.

The first finger 351 includes a first connection portion 3511, a first intermediate portion 3513, and a first main body portion 3515, and the second finger 353 includes a second connection portion 3531, a second intermediate portion 3533, and a second main body portion 3535. The first main body portion 3515 and the second main body portion 3535 have an overlapping area along the propagation direction of the acoustic wave. The first connection portion 3511 is connected to the first busbar 31, and the first intermediate portion 3513 is disposed between the first connection portion 3511 and the first main body portion 3515, with a first gap 355 between the first intermediate portion 3513 and the end of the second main body portion 3535. The first connection portion 3511 and the first main body portion 3515 have a distance difference along the propagation direction of the acoustic wave, and the first intermediate portion 3513 is disposed at an angle relative to the first main body portion 3515. The first busbar 31, the first connection portion 3511, and the first intermediate portion 3513 are connected to form a first opening 37 facing the propagation direction of the acoustic wave. The second connection portion 3531 is connected to the second busbar 33, and the second intermediate portion 3533 is disposed between the second connection portion 3531 and the second main body portion 3535, with a second gap 357 between the second intermediate portion 3533 and the first main body portion 3515. The second connection portion 3531 and the second main body portion 3535 have a distance difference along the propagation direction of the acoustic wave, and the second intermediate portion 3533 is disposed at an angle relative to the second connection portion 3531. The second busbar 33, the second connection portion 3531, and the second intermediate portion 3533 are connected to form a second opening 39, the orientation of which is opposite to that of the first opening 37.

The designs and advantageous effects of the parameters of the first busbar 31, the second busbar 33, the first connection portion 3511, the first intermediate portion 3513, the first main body portion 3515, the second connection portion 3531, the second intermediate portion 3533, the second main body portion 3535, and the piston structure 55 in the resonator 1 may refer to the foregoing embodiments, and are not repeated herein.

Thus, the shapes of the first finger 351 and the second finger 353 are modified between the end of the second main body portion 3535 and the first busbar 31, and between the end of the first main body portion 3515 and the second busbar 33, respectively. This changes the potentials of spurious modes in the gap regions between the busbars and the finger ends, reduces the potential difference of the spurious modes in the gap regions, and makes the potential distribution of the spurious modes in the gap regions more uniform. This helps suppress secondary excitation of acoustic waves between the end of the first main body portion 3515 and the second busbar 33, reduces stray acoustic waves, thereby further suppressing spurious modes and contributing to an increase in the Q factor.

Furthermore, since the first connection portion 3511 and the first main body portion 3515 are offset from each other along the propagation direction of the acoustic wave, the first intermediate portion 3513 and the first main body portion 3515 are arranged at an angle, and the first busbar 31, the first connection portion 3511, and the first intermediate portion 3513 are connected to form a first opening 37 oriented away from the first connection portion 3511, the resonator can better suppress spurious modes compared to a resonator without the above offset, angled arrangement, and opening.

In addition, the resonator 1 may further include a dielectric layer, the dielectric layer being disposed on the piezoelectric substrate 10 and covering the IDT 30.

It is to be understood that the dielectric layer may be at least one of a temperature compensation layer, a frequency tuning layer, or a passivation layer. The dielectric layer may be a single layer or a multilayer, which is not limited herein. When serving as a passivation layer, the dielectric layer can protect the IDT 30 and help prevent damage to the IDT 30. When serving as a temperature compensation layer, the dielectric layer can adjust the frequency temperature coefficient of the resonator 1. When serving as a frequency tuning layer, the dielectric layer can adjust the frequency of the resonator 1.

The dielectric layer may be made of materials such as silicon oxide, silicon nitride, or silicon oxynitride.

Referring to FIGS. 1, 3, and 16, the present embodiment also provides a method for manufacturing the resonator 1, the method including:
forming an IDT 30 on the substrate.

It is to be understood that the substrate at least includes the first dielectric layer 40 and the piezoelectric substrate 10. A second dielectric layer 80 may further be disposed between the first dielectric layer 40 and the piezoelectric substrate 10. The second dielectric layer 80 may be a single thin film layer or a multilayer thin film. Descriptions of the first dielectric layer 40, the second dielectric layer 80, and the piezoelectric substrate 10 may be referred to the corresponding descriptions in the above embodiments and are not repeated herein.

It is to be understood that the second dielectric layer 80 and the piezoelectric substrate 10 may be formed by a deposition method or by a bonding method, which is not limited herein.

Specifically, the shape of the IDT 30, particularly the formation of the first finger 351 and the second finger 353, may be formed through processes such as coating, exposure, development, deposition, and lift-off, etc. The specific manufacturing processes can be referred to the prior art and are not repeated herein.

The IDT 30 includes a first busbar 31 and a second busbar 33 disposed opposite to each other on the piezoelectric substrate 10, and a plurality of pairs of fingers disposed between the first busbar 31 and the second busbar 33. At least one finger pair 350 of the plurality of finger pairs includes alternately arranged first fingers 351 and second fingers 353. The first finger 351 is connected to the first busbar 31 and is spaced from the second busbar 33. The second finger 353 is connected to the second busbar 33 and is spaced from the first busbar 31. The first finger 351 includes a first connection portion 3511, a first intermediate portion 3513, and a first main body portion 3515. The second finger 353 includes a second connection portion 3531, a second intermediate portion 3533, and a second main body portion 3535. The first main body portion 3515 and the second main body portion 3535 have an overlapping region along the propagation direction of the acoustic wave. The first connection portion 3511 is connected to the first busbar 31, and the first intermediate portion 3513 is disposed between the first connection portion 3511 and the first main body portion 3515. There is a distance difference between the first connection portion 3511 and the first main body portion 3515 along the propagation direction of the acoustic wave, and the first intermediate portion 3513 is disposed at an angle relative to the first main body portion 3515. The second connection portion 3531 is connected to the second busbar 33, and the second intermediate portion 3533 is disposed between the second connection portion 3531 and the second main body portion 3535. There is a distance difference between the second connection portion 3531 and the second main body portion 3535 along the propagation direction of the acoustic wave, and the second intermediate portion 3533 is disposed at an angle relative to the second connection portion 3531. The first intermediate portion 3513 is disposed between the first connection portion 3511 and the second main body portion 3535, and a first gap 355 is formed between the first intermediate portion 3513 and the end of the second main body portion 3535. The second intermediate portion 3533 is disposed between the second connection portion 3531 and the first main body portion 3515, and a second gap 357 is formed between the second intermediate portion 3533 and the first main body portion 3515.

Furthermore, the technical features of the resonator 1 can be referred to the content in the above embodiments, and the corresponding descriptions and effects may be referred to the above embodiments, which are not repeated herein.

Referring to FIGS. 1 and 16, the present embodiment also provides another resonator 1, in which the shapes of all fingers 35 are altered at the first gap 355 and the second gap 357, thereby further improving the overall performance of the resonator 1.

Specifically, the resonator 1 includes a first dielectric layer 40, a second dielectric layer 80, a piezoelectric substrate 10, an IDT 30, and a passivation layer 95, which are stacked sequentially. The thickness of the first dielectric layer 40 is greater than that of the piezoelectric substrate 10, and the temperature coefficient of the first dielectric layer 40 is smaller than that of the piezoelectric substrate 10. Accordingly, the first dielectric layer 40 can provide temperature compensation for the piezoelectric substrate 10 to reduce the frequency temperature coefficient of the resonator 1, which helps to mitigate the influence of temperature on acoustic wave propagation and improves the operational performance of the resonator 1. Furthermore, by arranging the first dielectric layer 40 with greater thickness, higher acoustic velocity, and smaller temperature coefficient beneath the piezoelectric substrate 10, the acoustic velocity of the piezoelectric substrate 10 can also be increased.

The thicknesses of the second dielectric layer 80 and the piezoelectric substrate 10 are both smaller than that of the first dielectric layer 40, and the acoustic velocities of the piezoelectric substrate 10 and the first dielectric layer 40 are both greater than that of the second dielectric layer 80. This configuration helps to reduce the longitudinal leakage of acoustic wave energy.

It is to be noted that, in the resonator 1 provided in this embodiment, the second dielectric layer 80 may be a single-layer film or a multi-layer film. Its specific structure and beneficial effects can be referred to the above embodiments and are not repeated herein.

The passivation layer 95 covers the IDT 30. The passivation layer 95 can protect the IDT 30 to prevent corrosion or damage caused by the external environment.

The IDT 30 is disposed on the side of the piezoelectric substrate 10 opposite to the first dielectric layer 40. The IDT 30 includes a first busbar 31 and a second busbar 33 disposed opposite to each other on the piezoelectric substrate 10, a plurality of first fingers 351, and a plurality of second fingers 353. The first fingers 351 and the second fingers 353 are alternately arranged. The first fingers 351 are connected to the first busbar 31 and are spaced from the second busbar 33, while the second fingers 353 are connected to the second busbar 33 and are spaced from the first busbar 31. Each first finger 351 includes a first connection portion 3511, a first intermediate portion 3513, and a first main body portion 3515. Each second finger 353 includes a second connection portion 3531, a second intermediate portion 3533, and a second main body portion 3535. The first main body portion 3515 and the second main body portion 3535 have an overlapping region along the propagation direction of the acoustic wave. The first connection portion 3511 is connected to the first busbar 31, and the first intermediate portion 3513 is connected between the first connection portion 3511 and the first main body portion 3515. The first connection portion 3511 and the first main body portion 3515 have a distance difference along the propagation direction of the acoustic wave, and the first intermediate portion 3513 is arranged at an angle relative to the first main body portion 3515. The second connection portion 3531 is connected to the second busbar 33, and the second intermediate portion 3533 is connected between the second connection portion 3531 and the second main body portion 3535. The second connection portion 3531 and the second main body portion 3535 have a distance difference along the propagation direction of the acoustic wave, and the second intermediate portion 3533 is arranged at an angle relative to the second connection portion 3531. The first intermediate portion 3513 is located between the first connection portion 3511 and the second main body portion 3535, with a first gap 355 formed between the first intermediate portion 3513 and the end of the second main body portion 3535. The second intermediate portion 3533 is located between the second connection portion 3531 and the first main body portion 3515, with a second gap 357 formed between the second intermediate portion 3533 and the first main body portion 3515. Accordingly, the shapes of the first finger 351 and the second finger 353 are altered between the end of the second main body portion 3535 and the first busbar 31, as well as between the end of the first main body portion 3515 and the second busbar 33. This configuration reduces the potential difference in the gap regions, weakens the intensity of excitation sources located in the gap regions, suppresses secondary excitation of these sources, and reduces spurious acoustic waves. As a result, undesired modes generated in the gap regions are suppressed, and lateral spurious modes are also more effectively suppressed.

The technical features of the resonator 1 can refer to the contents of the above embodiments, and the corresponding descriptions and effects can also refer to the above embodiments, which will not be repeated herein.

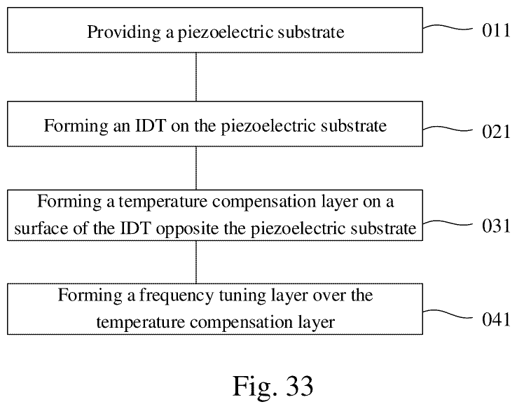

Referring to FIGS. 1, 29, and 33, the present embodiment further provides a method for manufacturing the resonator 1, which includes steps S011, S021, S031, and S041.

Step S011: Providing a piezoelectric substrate 10.

The material of the piezoelectric substrate 10 is lithium niobate.

Step S021: Forming an IDT 30 on the piezoelectric substrate 10.

The shape of the IDT 30, particularly the formation of the first fingers 351 and the second fingers 353, can be formed by processes such as coating, exposure, development, deposition, and lift-off. The specific manufacturing process can refer to the prior art and will not be repeated herein.

The IDT 30 includes two electrode assemblies disposed opposite to each other. Each electrode assembly includes a busbar and a plurality of fingers connected to the busbar. Among the plurality of fingers, at least one is a bent finger. The bent finger includes, in sequence, a connection portion, an intermediate portion, and a main body portion. One end of the connection portion is connected to the busbar, and the other end of the connection portion is connected to one end of the intermediate portion, while the other end of the intermediate portion is connected to the main body portion. The connection portion and the intermediate portion are arranged at an angle, and the main body portion and the intermediate portion are also arranged at an angle. An opening is formed between the intermediate portion, the connection portion, and the busbar, facing away from the connection portion. The connection portion and the main body portion have a distance difference along the propagation direction of the acoustic wave. The fingers 35 of the two electrode assemblies are alternately spaced and have an overlapping region along the propagation direction of the acoustic wave. A gap is formed between the intermediate portion of the bent finger of one electrode assembly and the main body portion of the bent finger of the other electrode assembly.

Moreover, the parameters, structural design, and beneficial effects of the busbars and bent fingers of the resonator 1 can refer to the above embodiments, which will not be repeated herein.

Step S031: Forming a temperature compensation layer 70 on a surface of the IDT 30 opposite the piezoelectric substrate 10.

The temperature compensation layer 70 is configured to adjust the frequency temperature coefficient of the resonator 1.

Step S041: Forming a frequency tuning layer 90 over the temperature compensation layer 70.

The frequency tuning layer 90 can be made of materials such as silicon oxide or silicon nitride. The structure and beneficial effects of the frequency tuning layer 90 can refer to the descriptions of the above embodiments and will not be repeated herein.

Referring to FIGS. 1 and 29, the present embodiment further provides another resonator 1 in which all the fingers 35 adopt a bent finger structure, thereby further improving the overall performance of the resonator 1.

Specifically, the resonator 1 includes a piezoelectric substrate 10, an IDT 30, a temperature compensation layer 70, and a frequency tuning layer 90. The material of the piezoelectric substrate 10 is lithium niobate. The IDT 30 is disposed on the piezoelectric substrate 10. The temperature compensation layer 70 covers the surface of the IDT 30 opposite the piezoelectric substrate 10 and is configured to adjust the frequency temperature coefficient of the resonator 1. The frequency tuning layer 90 can be disposed on the surface of the temperature compensation layer 70 opposite the IDT 30. The IDT 30 includes two electrode assemblies disposed opposite each other. Each electrode assembly includes a busbar and a plurality of bent fingers connected to the busbar. Each bent finger sequentially includes a connection portion, an intermediate portion, and a main body portion. One end of the connection portion is connected to the busbar, and the other end of the connection portion is connected to one end of the intermediate portion, while the other end of the intermediate portion is connected to the main body portion. The connection portion and the intermediate portion are arranged at an angle, and the main body portion and the intermediate portion are arranged at an angle. An opening is formed between the intermediate portion, the connection portion, and the busbar, facing away from the connection portion. The connection portion and the main body portion have a distance difference along the propagation direction of the acoustic wave. The fingers 35 of the two electrode assemblies are alternately spaced and have an overlapping region along the propagation direction of the acoustic wave. A gap is formed between the intermediate portion of the bent finger of one electrode assembly and the main body portion of the bent finger of the other electrode assembly.

Moreover, the parameters, structural design, and beneficial effects of the busbars and bent fingers of the resonator 1 can refer to the above embodiments and will not be repeated herein.

The present embodiment also provides a filter, wherein the filter includes the resonator 1 according to any of the above embodiments. Since the resonator 1 has reduced spurious modes, the filter can achieve not only a higher Q factor but also reduced spurious signals within the passband, thereby decreasing in-band fluctuations and improving the insertion loss of the filter.

In some embodiments, the filter may include a plurality of resonators 1, and the plurality of resonators 1 can be arranged as needed. The number of resonators 1 may be two, three, four, or more.

In some embodiments, the filter may be a ladder-type filter. The ladder-type filter may include a plurality of series-arm resonators 1 and a plurality of parallel-arm resonators 1, and at least one of the series-arm resonators 1 or parallel-arm resonators 1 is the resonator 1 according to any of the above embodiments.

In other embodiments, the filter may be of another type.

Moreover, since the filter includes the resonator 1, the filter has all the advantageous effects of the resonator 1, which will not be repeated herein.

The present embodiment also provides an RF front-end module, wherein the RF front-end module includes the filter according to the above embodiments. Due to the reduction of spurious modes and the improvement of the Q factor in the resonator 1, the filter performance can be improved, thereby enhancing the performance of the RF front-end module.

In some embodiments, the RF front-end module can be applied to electronic devices, and the electronic devices may include, but are not limited to, LED panels, tablet computers, laptops, computers, navigators, mobile phones, and electronic watches or components having a PCB. The present application is not limited thereto.

In some embodiments, the RF front-end module may include a plurality of filters, and the number of filters may be two, three, or more.

In some embodiments, the RF front-end module may further include a low-noise amplifier, an RF switch, and a power amplifier, and the specific connection thereof can refer to the prior art, which will not be repeated herein.

Moreover, since the RF front-end module includes the filter, and the filter includes the resonator 1, the RF front-end module possesses all the advantageous effects of both the filter and the resonator 1, which will not be repeated herein.

In the resonator 1, filter, RF front-end module, and the method for manufacturing the resonator 1 according to the present embodiment, the resonator 1 includes a piezoelectric substrate 10 and an IDT 30, wherein the IDT 30 is disposed on the piezoelectric substrate 10. The first finger 351 includes a first connection portion 3511, a first intermediate portion 3513, and a first main body portion 3515, and the second finger 353 includes a second connection portion 3531, a second intermediate portion 3533, and a second main body portion 3535. The first main body portion 3515 and the second main body portion 3535 have an overlapping region along the propagation direction of the acoustic wave. The first connection portion 3511 is connected to the first busbar 31, and the first intermediate portion 3513 is connected between the first connection portion 3511 and the first main body portion 3515, with a first gap 355 formed between the first intermediate portion 3513 and the end of the second main body portion 3535. The first connection portion 3511 and the first main body portion 3515 have a distance difference along the propagation direction of the acoustic wave, and the first intermediate portion 3513 and the first main body portion 3515 are disposed at an angle. The first busbar 31, the first connection portion 3511, and the first intermediate portion 3513 together form a first opening 37 facing away from the first connection portion 3511. The second connection portion 3531 is connected to the second busbar 33, and the second intermediate portion 3533 is connected between the second connection portion 3531 and the second main body portion 3535, with a second gap 357 formed between the second intermediate portion 3533 and the first main body portion 3515. The second connection portion 3531 and the second main body portion 3535 have a distance difference along the propagation direction of the acoustic wave, and the second intermediate portion 3533 and the second connection portion 3531 are disposed at an angle. The second busbar 33, the second connection portion 3531, and the second intermediate portion 3533 together form a second opening 39, which faces opposite to the first opening 37. In the SAW resonator 1, the shapes of the fingers at the ends of the main body portions and between the main body portions and the busbars are modified, which can reduce the potential difference in the gap regions and weaken the strength of the excitation sources located therein. As a result, secondary excitations of the excitation sources are suppressed, and spurious modes can be effectively reduced. Moreover, the resonator 1 provided in the present embodiment can suppress spurious modes, including lateral spurious modes, simply by modifying the shapes of the fingers. This can be achieved without forming piston structures in the overlapping regions, thereby avoiding restrictions on the widths of the fingers or the spacing between adjacent fingers. Consequently, the operating frequency band of the resonator 1 is not limited, allowing the frequency of the resonator 1 to be increased under the same process conditions, or the size of the resonator 1 to be reduced at the same frequency.

In the present application, unless otherwise explicitly specified or limited, terms such as “mounted” or “connected” should be understood in a broad sense. For example, they may refer to a fixed connection or a detachable connection, or an integral connection; they may refer to a mechanical connection; they may be a direct connection, or an indirect connection through an intermediate medium; they may refer to communication within two components, or merely surface contact, or surface contact through an intermediate medium. A person skilled in the art can understand the specific meaning of the above terms in this application according to the particular circumstances.

Furthermore, terms such as “first” and “second” are used merely to distinguish different elements or features and should not be construed as indicating any specific order or special structure. Expressions such as “some embodiments” or “other embodiments” are intended to indicate that the particular features, structures, materials, or characteristics described in connection with that embodiment or example are included in at least one embodiment or example of the present application. In this application, the schematic use of these terms does not necessarily refer to the same embodiment or example. Moreover, the described specific features, structures, materials, or characteristics can be combined in any suitable manner in one or more embodiments or examples. In addition, provided there is no contradiction, a person skilled in the art can combine and integrate the different embodiments or examples described in this application and their respective features.

The above embodiments are provided solely to illustrate the technical solutions of the present application, and are not intended to limit them. Although the present application has been described in detail with reference to the foregoing embodiments, a person skilled in the art should understand that modifications to the technical solutions disclosed in the above embodiments, or equivalent replacements of some technical features, can still be made without departing from the spirit and scope of the technical solutions of the embodiments of the present application, and such modifications or replacements should be considered as falling within the protection scope of the present application.

1. A resonator, comprising:
a piezoelectric substrate; and
an interdigital transducer (IDT) arranged on the piezoelectric substrate, wherein the IDT comprises:
a first busbar and a second busbar arranged opposite to each other on the piezoelectric substrate; and
a plurality of finger pairs located between the first busbar and the second busbar;
wherein at least one of the plurality of finger pairs comprises first fingers and second fingers alternately spaced, the first fingers being connected to the first busbar and spaced apart from the second busbar, and the second fingers being connected to the second busbar and spaced apart from the first busbar;
wherein each of the first fingers comprises a first connection portion, a first intermediate portion, and a first main body portion, and each of the second fingers comprises a second connection portion, a second intermediate portion, and a second main body portion; the first main body portion and the second main body portion have an overlapping area along a propagation direction of an acoustic wave;
the first connection portion is connected to the first busbar, the first intermediate portion is connected between the first connection portion and the first main body portion, and a first gap is provided between the first intermediate portion and an end of the second main body portion; the first connection portion and the first main body portion are offset from each other along the propagation direction of the acoustic wave, the first intermediate portion and the first main body portion are arranged at an angle; the first busbar, the first connection portion, and the first intermediate portion are connected to form a first opening, and the first opening is oriented away from the first connection portion;
the second connection portion is connected to the second busbar, the second intermediate portion is connected between the second connection portion and the second main body portion, and a second gap is provided between the second intermediate portion and the first main body portion; the second connection portion and the second main body portion are offset from each other along the propagation direction of the acoustic wave, the second intermediate portion and the second connection portion are arranged at an angle; the second busbar, the second connection portion, and the second intermediate portion are connected to form a second opening, and the second opening is oriented in a direction opposite to that of the first opening.

2. (canceled)

3. (canceled)

4. The resonator of claim 1, wherein
the resonator has at least one of the following features:
widths of the first intermediate portion and the second intermediate portion in the direction from the first busbar toward the second busbar are each defined as L1, and 0.1λ≤L1≤0.4λ;
duty ratios of the first fingers and the second fingers are each defined as DF, and 0.3≤DF≤0.6;
duty ratios of the first fingers and the second fingers are defined as DF, lengths of the first intermediate portion and the second intermediate portion in the propagation direction of the acoustic wave are defined as W1, and
$$( 1 + DF ) * \frac{λ}{2} \leq W 1 < λ ;$$
widths of the first gap and the second gap are each defined as L2, where 0.1λ≤L2≤0.8λ;
widths of the first intermediate portion and the second intermediate portion in the direction from the first busbar toward the second busbar are defined as L1, widths of the first gap and the second gap are each defined as L2, and L1+L2≤λ;
a distance from the first busbar to the first intermediate portion is greater than a width of the first gap, and a distance from the second busbar to the second intermediate portion is greater than a width of the second gap;
where λ represents a wavelength of the acoustic wave.

5. The resonator of claim 1, wherein
distances between two ends of the first intermediate portion or between two ends of the second intermediate portion in the direction from the first busbar toward the second busbar are defined as L, where L=λA;
angles between the first intermediate portion and the first main body portion and between the second intermediate portion and the second main body portion are each defined as θ; and
$$θ = 90 ° + arcsin ( 2 A / \sqrt{1 + 4 * {A}^{2}} )$$
where 0≤A≤0.3, and λ is a wavelength of the acoustic wave.

6. (canceled)

7. The resonator of claim 1, further comprising a first dummy finger and a second dummy finger, wherein one end of the first dummy finger is connected to the first busbar and another end is spaced from the first intermediate portion; and one end of the second dummy finger is connected to the second busbar and another end is spaced from the second intermediate portion.

8. The resonator of claim 7, wherein the first dummy finger and the second dummy finger are arranged with apodization between the first busbar and the second busbar.

9. (canceled)

10. The resonator of claim 1, wherein
the resonator further comprises a first conductive strip and a second conductive strip;
the first conductive strip is located between the first intermediate portion and the first busbar and is connected to at least the first connection portion of the first finger;
the second conductive strip is located between the second intermediate portion and the second busbar and is connected to at least the second connection portion of the second finger;
or the first conductive strip is discontinuously arranged between the first intermediate portion and the first busbar, and the second conductive strip is discontinuously arranged between the second intermediate portion and the second busbar.

11. (canceled)

12. The resonator of claim 1, wherein
the first connection portion and the second main body portion overlap with each other in the direction from the first busbar toward the second busbar, and the second connection portion and the first main body portion overlap with each other in the direction from the first busbar toward the second busbar;
or the first connection portion and the second connection portion overlap with each other in the direction from the first busbar toward the second busbar and are located between the first main body portion and the second main body portion.

13. (canceled)

14. A resonator, comprising:
a first dielectric layer and a piezoelectric substrate laminated together, with a thickness of the first dielectric layer being greater than that of the piezoelectric substrate, and a temperature coefficient of the first dielectric layer being smaller than that of the piezoelectric substrate; and
an interdigital transducer (IDT) arranged on a side of the piezoelectric substrate opposite to the first dielectric layer, wherein the IDT comprises:
a first busbar and a second busbar arranged opposite to each other on the piezoelectric substrate; and
a plurality of finger pairs located between the first busbar and the second busbar;
wherein at least one of the plurality of finger pairs comprises first fingers and second fingers alternately arranged, the first fingers being connected to the first busbar and spaced apart from the second busbar, and the second fingers being connected to the second busbar and spaced apart from the first busbar;
wherein each of the first fingers comprises a first connection portion, a first intermediate portion, and a first main body portion, and each of the second fingers comprises a second connection portion, a second intermediate portion, and a second main body portion; the first main body portion and the second main body portion have an overlapping area along a propagation direction of an acoustic wave;
the first connection portion is connected to the first busbar, and the first intermediate portion is connected between the first connection portion and the first main body portion; the first connection portion and the first main body portion are offset from each other along the propagation direction of the acoustic wave, and the first intermediate portion and the first main body portion are arranged at an angle;
the second connection portion is connected to the second busbar, and the second intermediate portion is connected between the second connection portion and the second main body portion; the second connection portion and the second main body portion are offset from each other along the propagation direction of the acoustic wave, and the second intermediate portion and the second connection portion are arranged at an angle;
the first intermediate portion is located between the first connection portion and the second main body portion, with a first gap provided between the first intermediate portion and an end of the second main body portion; the second intermediate portion is located between the second connection portion and the first main body portion, with a second gap provided between the second intermediate portion and the first main body portion.

15. The resonator of claim 14, further comprising a second dielectric layer located between the first dielectric layer and the piezoelectric substrate;
wherein thicknesses of the second dielectric layer and the piezoelectric substrate are each smaller than the thickness of the first dielectric layer, and acoustic velocities of the piezoelectric substrate and the first dielectric layer are each greater than that of the second dielectric layer.

16. The resonator of claim 15, wherein
the second dielectric layer is a single-layer film or a multi-layer film;
the second dielectric layer at least comprises a first film layer, with an acoustic velocity of the first film layer being smaller than that of the piezoelectric substrate, or an acoustic impedance of the first film layer being smaller than that of the piezoelectric substrate.

17. (canceled)

18. The resonator of claim 14, wherein
widths of the first intermediate portion and the second intermediate portion in a direction from the first busbar toward the second busbar are each defined as L1, where λ≥L1≥0.1λ;
and λ is a wavelength of the acoustic wave.

19. The resonator of claim 14, wherein the resonator has at least one of the following features:
widths of the first gap and the second gap are each defined as L2, where 1.15λ≥L2≥0.125λ;
distances from the first busbar to the first intermediate portion and from the second busbar to the second intermediate portion are each defined as L3, where 3λ≥L3≥0.125λ;
duty ratios of the first finger and the second finger are each defined as DF, where 0.6≥DF≥0.25;
and λ is a wavelength of the acoustic wave.

20. The resonator of claim 14, wherein
the first main body portion and the second main body portion each have a piston structure in the overlapping area, with the piston structures being located on opposite sides of the overlapping area in the direction from the first busbar toward the second busbar.

21. The resonator of claim 20, wherein
a length of the piston structures in a direction from the first busbar toward the second busbar is defined as f, where 2λ≥f≥0.1;
and λ is a wavelength of the acoustic wave.

22. The resonator of claim 14, further comprising a passivation layer covering the IDT.

23. A resonator, comprising:
a piezoelectric substrate, with the piezoelectric substrate being made of lithium niobate; and
an interdigital transducer and a temperature compensation layer, with the IDT being arranged on the piezoelectric substrate, the temperature compensation layer covering a surface of the IDT, the temperature compensation layer being configured to adjust a frequency temperature coefficient of the resonator;
wherein the IDT comprises two electrode assemblies arranged opposite to each other, with each electrode assembly comprising a busbar and a plurality of fingers connected thereto, at least one of the fingers being a bent finger;
wherein the bent finger comprises: in sequence, a connection portion, an intermediate portion, and a main body portion;
wherein one end of the connection portion is connected to the busbar, another end of the connection portion is connected to one end of the intermediate portion, and another end of the intermediate portion is connected to the main body portion; the connection portion and the intermediate portion is arranged at an angle, the main body portion and the intermediate portion is arranged at an angle; the intermediate portion, the connection portion, and the busbar form an opening oriented away from the connection portion, and the connection portion and the main body portion are offset from each other along a propagation direction of an acoustic wave;
wherein the fingers of the two electrode assemblies are alternately spaced, have an overlapping area along the propagation direction of the acoustic wave, and a gap is provided between the intermediate portion of the bent finger of one of the electrode assemblies and the main body portion of the bent finger of another electrode assembly.

24. (canceled)

25. The resonator of claim 23, wherein the resonator has at least one of the following features:
a width of the gap defined as L2, 1.15λ≥L2≥0.125λ;
a length of the intermediate portion along a direction of arrangement of the two busbars defined as L1, 0.15λ≤L1≤0.5λ;
a distance between the busbar and the intermediate portion defined as L3, 0.5λ≤L3≤2.5λ;
and λ is a wavelength of the acoustic wave.

26. The resonator of claim 23, wherein a width of the gap is defined as L2, a length of the intermediate portion along a direction of arrangement of the two busbars is defined as L1, a distance between the busbar and the intermediate portion is defined as L3, where L1+L2≤L3, and λ≤L1+L2+L3≤3.5λ;
and λ is a wavelength of the acoustic wave.

27. The resonator of claim 23, wherein the IDT further comprises piston structures, with the piston structures being located on opposite sides of the overlapping area along the direction of arrangement of the two busbars, and configured to increase a mass load of the main body portion on the opposite sides within the overlapping area.

28. The resonator of claim 27, wherein a width of the piston structures along the propagation direction of the acoustic wave is defined as W2, where 0.1×λ/2≤W2≤DF×λ/2;
and λ is a wavelength of the acoustic wave, DF is a duty ratio of the first fingers and the second fingers.

29. (canceled)

30. (canceled)

31. (canceled)

32. (canceled)

33. (canceled)
